(19) United States
(12) Patent Application Publication
(10) Pub. No.: US 2025/0372156 A1
(43) Pub. Date: Dec. 4, 2025

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Ching-Wang YAO, New Taipei City (TW); Je-Min HUNG, Hsinchu City (TW); Hidehiro FUJIWARA, Hsinchu City (TW); Chee-Wee LIU, Taipei City (TW); Hung-Jen LIAO, Hsinchu City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/731,026

(22) Filed: May 31, 2024

(51) Int. Cl. G11C 11/412; G11C 11/419; H01L 21/8238; H01L 27/092; H01L 29/06; H01L 29/423; H01L 29/786; H10B 10/00

(52) U.S. Cl. CPC G11C 11/412; G11C 11/419; H10B 10/12; H10D 30/6735; H10D 30/6757; H10D 62/118; H10D 84/0167; H10D 84/038; H10D 84/85

(57) ABSTRACT

A method includes forming a first read pull-down transistor and a first read pass-gate transistor over a substrate at a first level height, wherein the first read pull-down and first read pass-gate transistors are of a first read port of a static random access memory (SRAM) cell; forming a second read pull-down transistor and a second read pass-gate transistor over the substrate at a second level height higher than the first level height, wherein the second read pull-down and second read pass-gate transistors are of a second read port of the SRAM cell.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram in accordance with some embodiments of the present disclosure.

FIGS. 2-3E illustrate schematic views of a semiconductor structure in accordance with some embodiments of the present disclosure.

FIGS. 4A and 4B illustrate tables of operations of a semiconductor structure in accordance with some embodiments of the present disclosure.

FIGS. 5A-33 illustrate cross-sectional views of intermediate stages in the formation of a semiconductor structure in accordance with some embodiments.

FIGS. 34-35D illustrate schematic views of a semiconductor structure in accordance with some embodiments of the present disclosure.

FIG. 36A illustrates reading times in different semiconductor structures in accordance with some embodiments of the present disclosure.

FIG. 36B illustrates bit line voltage changes in different semiconductor structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

Embodiments of the present disclosure are applicable to compute-in-memory, processing-in-memory, processing-using-memory, near-memory-compute, near-data processing, near-memory processing, in-storage processing, GPU accelerator, TPU accelerator, In-memory computing, in-memory-processing, compute near memory, and/or processing near memory.

In CMOS technology, while effective in enhancing static random-access memory (SRAM) performance through multi-port configurations, may lead to an increased space consumption on the semiconductor chip. Therefore, the present disclosure in various embodiments provides a 10-transistor, 3-port (10T3P) SRAM configuration within the area occupied by a 6-transistor (6T) layout (i.e., 6T footprint). The SRAM bit cell of this disclosure can leverage complementary field-effect transistor (CFET) technology alongside a backside power delivery network (BSPDN). The SRAM bit cell of this disclosure can improve area efficiency, which in turn allows for enhancing high-performance computing, such as compute-in-memory (CIM) applications). Furthermore, the SRAM bit cell of this disclosure can have a read port using pFET-based gates, ensuring optimal performance and space utilization.

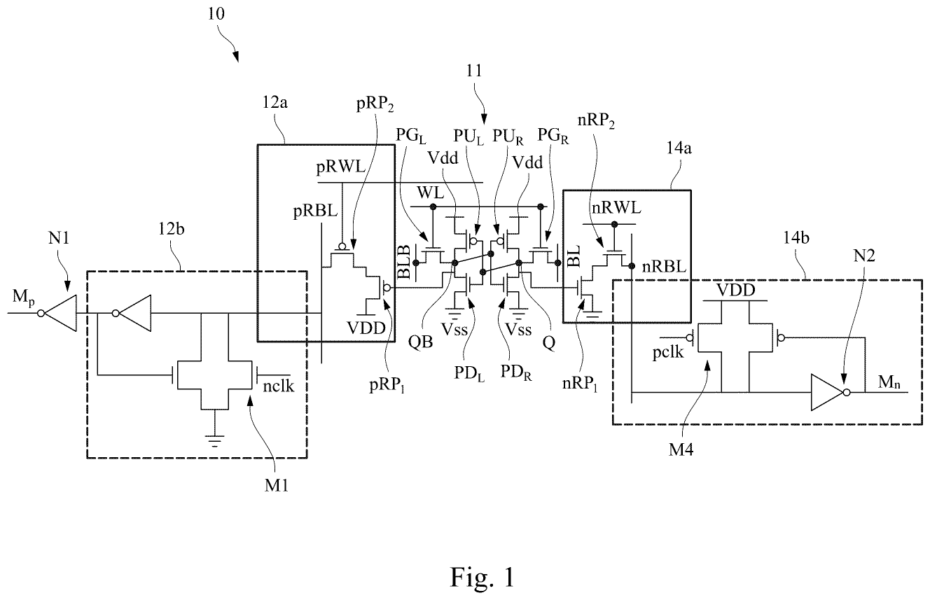

Reference is made to FIG. 1. FIG. 1 illustrates a circuit diagram in accordance with some embodiments of the present disclosure. Specifically, FIG. 1 depicts a static random-access memory (SRAM) cell arrangement that uses ten transistors (10T) with pre-discharge circuits 12b and 14b, in which the SRAM cell arrangement uses ten transistors (10T). A SRAM bit cell 10 that uses ten transistors (10T) and has an additional functionality in the form of read ports 12a and 14a. Thus this configuration may be referred to as a three port (3P) 10T SRAM bit cell 10. That is, the SRAM cell can include one write port 11 and two read ports 12a and 14a. The write port 11 can include pull-up transistors PU_{R}, and PU_{L}, and pull-down transistors PD_{R} and PD_{L} and pass-gate transistors PG_{R} and PG_{L}. The read port 12a can include read pull-down transistor pRP₁ and read pass-gate transistor pRP₂ connected in series. The read port 14a can include read pull-down transistor nRP₁ and read pass-gate transistor nRP₂ connected in series.

In this form, the circuit has two read ports 12a and 14a, one coupled to each storage node QB and B of a 6T cell. Each read port 12a and 14a can have a separate read word line (e.g., word lines pRWL and nRWL). In some embodiments, the read word lines pRWL and nRWL can be provided that is dedicated to “reads” only. In some embodiments, the read word line can be interchangeably referred to as a control line. In some embodiments, signals of the word lines pRWL and nRWL can either be interconnected to operate as a unified signal pathway or maintained as separate entities. Additionally, the read port 12a can have a pull down transistor pRP₁ and pass gate transistor pRP₂, and the read port 12a can have a pull down transistor nRP₁ and pass gate transistor nRP₂. The two read bit lines pRBL and nRBL can be coupled by the pass gate transistors pRP₂ and nRP₂ to the pull down transistors pRP₁ and nRP₁ respectively. The pull down transistors pRP₂ and nRP₂ each can have a gate terminal coupled with a respective storage node QB and Q. The read operations may be performed independently or simultaneously. The use of the two read ports 12a and 14a can provide additional flexibility and allows two outputs to be read from the cell simultaneously. In FIG. 1, the read port 12a can be electrically connected to the storage node QB, and the read port 14a can be electrically connected to the storage node Q. In some embodiments, the read port 12a can be electrically connected to the storage node Q, and the read port 14a can be electrically connected to the storage node QB.

In FIG. 1, a pair of MOS pass gates PG_{L} and PG_{R} can couple a pair of data lines referred to as bit lines BL and BLB to inversely related storage nodes QB and Q, respectively. The bit lines BL and BLB can form a complementary pair of data lines. In some embodiments, these paired data lines may be coupled to a differential sense amplifier (not shown); the differential voltage can be sensed and amplified. This amplified sensed output signal may then be output as data to other logic circuitry in the device. A supply voltage VDD, which may be from 0.6 Volts to 3.0 or more volts, depending on the technology node, is shown. Pull up transistors PU_{L} and PU_{R} can couple the positive supply to one or the other storage nodes, depending on the state of the SRAM bit cell 10. A second supply voltage Vss, usually placed at ground, is shown. Two pull down transistors PD_{L} and PD_{R} can couple negative or ground voltage Vss to one or the other storage nodes labeled QB and Q, depending on the state of the SRAM bit cell 10. The SRAM bit cell 10 can be a latch that will retain its data state indefinitely so long as the supplied power is sufficient to operate the circuit correctly.

Two CMOS inverters formed of transistors PU_{L}, PD_{R}, PU_{L}, and PD_{R} can be “cross coupled” and they can operate to reinforce the stored charge on the storage nodes QB and Q continuously. The two storage nodes QB and Q can be inverted one from the other, as shown in the figure. When SN1 is a logical “1”, usually a high voltage, SN2 is at the same time a logical “0”, usually a low voltage, and vice versa. When the SRAM bit cell 10 is written to, complementary write data signals are placed on the bit line pair BL and BLB. A positive control signal on a word line WL can be coupled to the gates of both pass gate transistors PG_{L} and PG_{R}. In some embodiments, the word line WL can be a write only word line in the SRAM bit cell 10, and thus the SRAM bit cell 10 can has one write port 11 and two separate read ports 12a and 14a. The transistors PU_{L}, PD_{R} PU_{L}, PD_{R} can be sized such that the data on the bit lines BL and BLB may overwrite the stored data and thus write, or program, the SRAM bit cell 10. When the SRAM bit cell 10 is in read from, a positive voltage is placed on the word line WL, and the pass gate transistors PG_{L} and PG_{R} allow the bit lines BL and BLB to be coupled to, and receive the data from, the storage nodes QB and Q. Unlike a dynamic memory cell, the SRAM bit cell does not lose its stored state during a read if the supply voltage Vdd is maintained at a sufficiently high level, so no “write back” operation is required after a cell read. Advantages of separate read ports are that the possibility of “read disturbs” can be reduced, because the data stored in the SRAM bit cell 10 is not affected by the read operations; instead, the read pull down transistor RPD is either on or off, based on the storage node Q voltage that is coupled to the gate terminal of the transistor RPD.

In some embodiments, the transistors nRP₁, nRP₂, PG_{R}, PG_{L}, PD_{R}, and PD_{L}, are of a first conductivity type, and the transistors pRP₁, pRP₂, PU_{R}, and PU_{L} are of a second conductivity type opposite to the first conductivity type. By way of example and not limitation, the transistors nRP₁, nRP₂, PG_{R}, PG_{L}, PD_{R}, and PD_{L} may be n-type transistors (e.g., N-type Metal-Oxide-Semiconductor (NMOS) transistors), and the pRP₁, pRP₂, PU_{R}, and PU_{L} may be p-type transistors (e.g., P-type Metal-Oxide-Semiconductor (PMOS) transistors). In some embodiments, the transistors nRP₁, nRP₂, PG_{R}, PG_{L}, PD_{R}, and PD_{L} may be p-type transistors (e.g., PMOS transistors), and the pRP₁, pRP₂, PU_{R}, and PU_{L} may be n-type transistors (e.g., NMOS transistors).

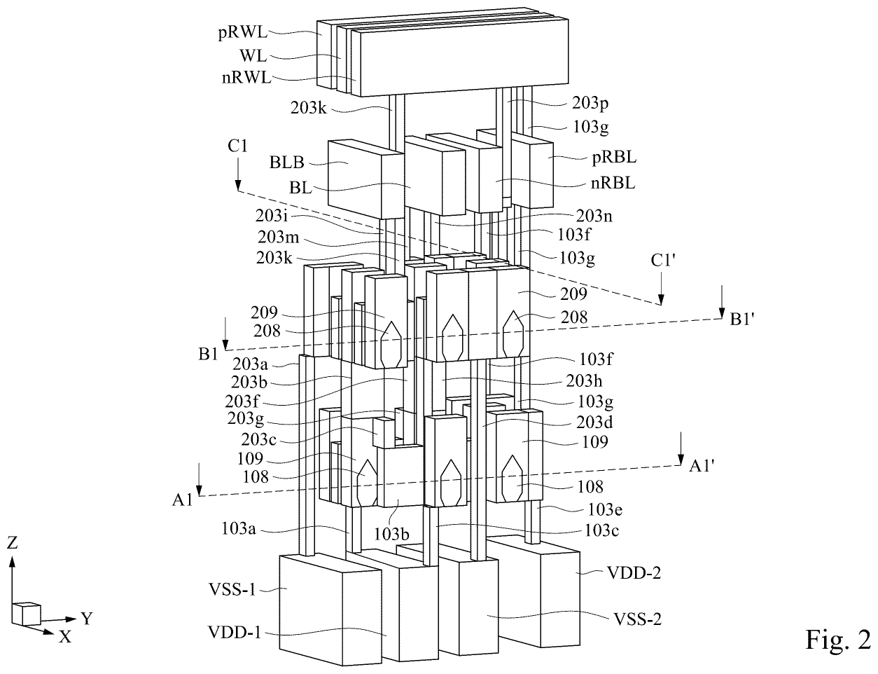

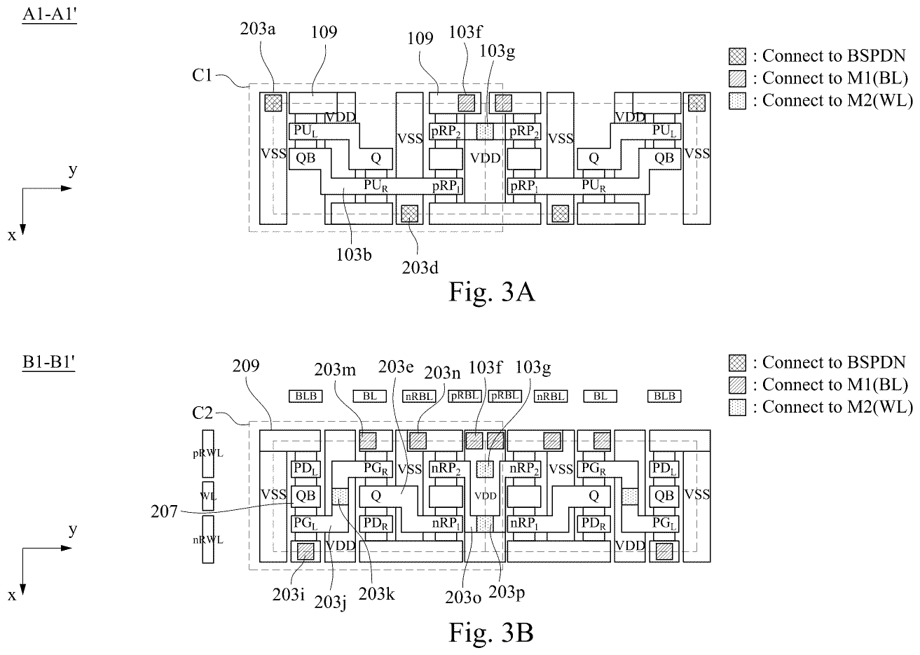

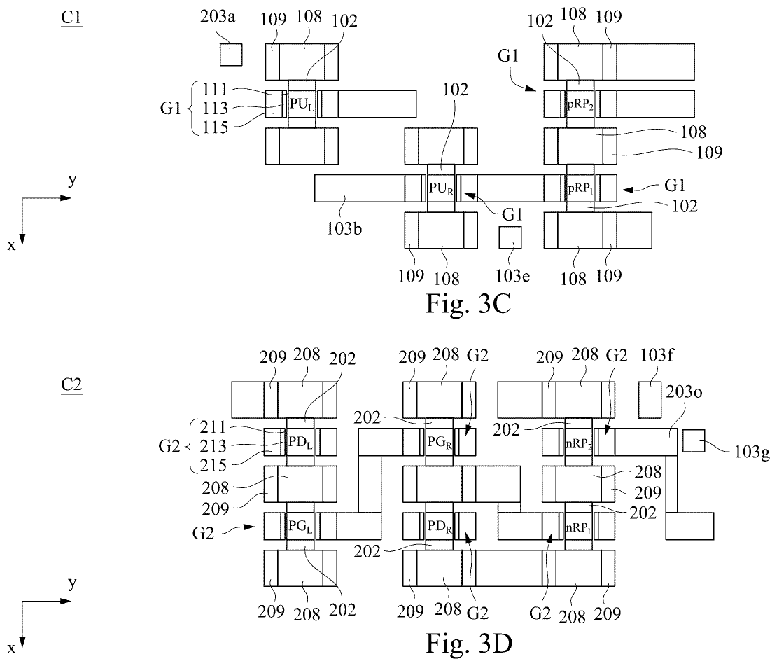

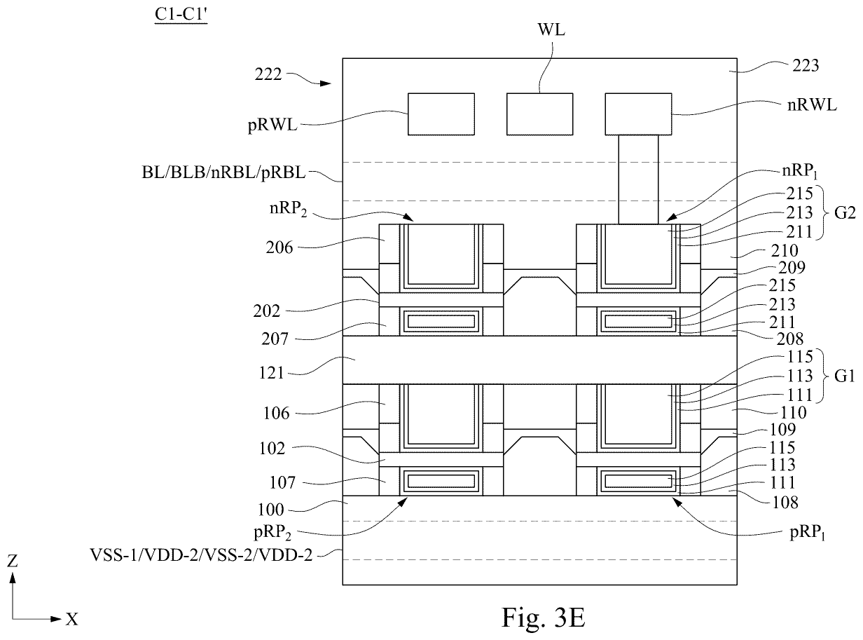

Reference is made to FIGS. 2-3E. FIGS. 2-3E illustrate schematic views of a semiconductor structure in accordance with some embodiments of the present disclosure. Specifically, FIG. 2 illustrates a perspective view a semiconductor structure in accordance with some embodiments of the present disclosure. FIGS. 3A, 3B, 3C illustrate cross-sectional views obtained from reference cross-sections A1-A1′, B1-B1′, and C1-C1′, respectively, in FIG. 2 in accordance with some embodiments of the present disclosure. FIGS. 3D and 3E illustrate local enlarged views of regions C1 and C2 in FIGS. 3A and 3B, respectively, in accordance with some embodiments of the present disclosure. The semiconductor structure can be a SRAM bit cell that uses ten transistors (10T) and has an additional functionality in the form of two read ports. The semiconductor structure can include transistors pRP₁ and pRP₂ and transistors PU_{R}, and PU_{L} (see FIGS. 2, 3A, and 3D) as bottom-tier transistors and the transistors nRP₁, nRP₂, PG_{R}, PG_{L}, PD_{R}, and PD_{L} (see FIGS. 2, 3B, and 3E) as top-tier transistors. In some embodiments, the transistors nRP₁, nRP₂, PG_{R}, PG_{L}, PD_{R}, PD_{L}, pRP₁, pRP₂, PU_{R}, and PU_{L} can be positioned at more than 2-tier. In other words, the transistors pRP₁, pRP₂, PU_{R}, and PU_{L} can be at a first level height, and the transistors nRP₁, nRP₂, PG_{R}, PG_{L}, PD_{R}, and PD_{L} can be at a second level height higher than the first level height. In some embodiments, the transistors of the SRAM bit cell 10 can include various channel geometries such as nanosheets, FinFETs, and nanowires.

As shown in FIGS. 2 and 3E, the transistors pRP₁, pRP₂, PU_{R}, and PU_{L} each includes the channel layer 102, the source/drain regions 108 on opposite sides of the channel layer 102 and connected to the channel layer 102, and the gate structure G1 wrapping around the channel layer 102. The transistors nRP₁, nRP₂, PG_{R}, PG_{L}, PD_{R}, and PD_{L} each includes the channel layer 202, the source/drain regions 208 on opposite sides of the channel layer 202 and connected to the channel layer 202, and the gate structure G2 wrapping around the channel layer 202. In some embodiments, the transistors pRP₁, pRP₂, PU_{R}, and PU_{L} can situated at a first level height, and the transistors nRP₁, nRP₂, PG_{R}, PG_{L}, PD_{R}, and PD_{L} can situated at a second level height higher than the first level height. By way of example but not limitation, the transistor nRP₁ can be over the transistor pRP₁, the transistor nRP₂ can be over the transistor pRP₂, the transistor PD_{R} can be over the transistor PU_{R}, and the transistor PD_{L} can be over the transistor PU_{L}. In some embodiments, the channel layer 102 and/or the channel layer 202 can be interchangeable referred to as a channel pattern, a channel region, a channel line, a semiconductive layer, or a semiconductive nanostructure. In some embodiments, the source/drain region 108 and/or the source/drain region 208 can be interchangeably referred to as a source/drain pattern, an epitaxial pattern, a source/drain structure, or an epitaxial structure. In some embodiments, the gate structure G1 and/or the gate structure G2 can be interchangeable referred to as a gate, a gate pattern, a gate strip, a gate layer, a gate layer, or a functional gate.

In FIGS. 2 and 3A, a first one of the source/drain regions 108 of the transistor PU_{L} can be electrically connected to the underlying voltage source line VDD-1 through a contact 103a (see FIG. 2), and a second one of the source/drain regions 108 of the transistor PU_{L} can be electrically connected to the gate structure G1 of the transistor PU_{R} through a contact 103b. A first one of the source/drain regions 108 of the transistor PU_{R} is electrically connected to the underlying voltage source line VDD-1 through a contact 103c (see FIG. 2), and a second one of the source/drain regions 108 of the transistor PU_{R} can be electrically connected to the gate structure G1 of the transistor PU_{L} through a contact 103d (see FIG. 3A).

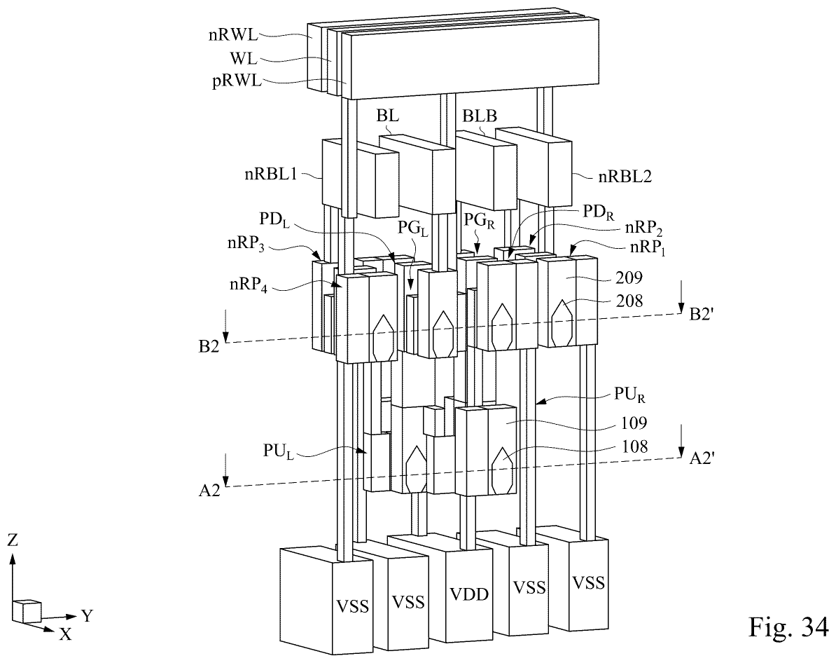

In FIGS. 2 and 3A, a first one of the source/drain regions 108 of the transistor pRP₁ is electrically connected to the underlying voltage source line VDD-2 thorough the contact 103e (see FIG. 2), and a second one of the source/drain regions 108 of the transistor pRP₁ is electrically connected to a source/drain node of the transistor pRP₂. In some embodiments, the transistor pRP₁ and the transistor pRP₂ can share the same source/drain region 108. The gate structure G1 of the transistor pRP₁ is electrically connected to the gate structure G1 of the transistor PU_{R}. One of the source/drain regions 108 of the transistor pRP₂ opposite to the transistor pRP₁ is electrically connected to the overlaying read bit lines pRBL (see FIG. 2) in the interconnect structure 222 (see FIG. 34) through a contact 103f, and the gate structure, and the gate structure G1 of the transistor pRP₂ is electrically connected to the overlying read word line pRWL in the interconnect structure 222 (see FIG. 34) through a contact 103g.

In FIGS. 2 and 3B, a first one of the source/drain region 208 of the transistor PD_{L} is electrically connected to the underlying ground line VSS-1 through the contact 203a (see FIG. 2), a second one of the source/drain region 208 of the transistor PD_{L} is electrically connected to a first source/drain node of the transistor PG_{L}. In some embodiments, the transistor PD_{L} and the transistor PG_{L} can share the same source/drain region 208. Additionally, the second one of the source/drain region 208 of the transistor PD_{L} is electrically connected to the second one of the source/drain regions 108 of the underlying transistor PU_{L} through a contact 203b and the underlying source/drain contact 109, and is further electrically connected to the gate structure G1 of the underlying transistor PU_{R} through a contact 203c and the contact 103b. The gate structure G2 of the transistor PD_{L} is electrically connected to the gate structure G2 of the underlying transistor PU_{L} through a contact (not shown).

In FIGS. 2 and 3B, a first one of the source/drain regions 208 of the transistor PD_{R} is electrically connected to a first one of the source/drain regions 108 of the transistor nRP₁ through the source/drain contact 209. Additionally, the first ones of the source/drain regions 208 of the transistors PD_{R} and nRP₁ are electrically connected the underlying ground line VSS-1 through the contact 203d (see FIG. 2). A second one of the source/drain regions 208 of the transistor PD_{R} is electrically connected to a source/drain node of the transistor PG_{R} and electrically connected to the gate structure G2 of the transistor nRP₁ through a contact 203e (see FIG. 3B). In some embodiments, the transistor PD_{R} and the transistor PG_{R} can share the same source/drain region 208. Additionally, the second one of the source/drain region 208 of the transistor PD_{L} is electrically connected to the second one of the source/drain regions 108 of the underlying transistor PU_{R} through a contact 203f (see FIG. 2) and the underlying source/drain contact (not shown), and is further electrically connected to the gate structure G1 of the underlying transistor PU_{L} through a contact 203g (see FIG. 2) and the contact 103d (see FIG. 3A). The gate structure G2 of the transistor PD_{R} is electrically connected to the gate structure G2 of the underlying transistor PU_{R} through a contact 203h (see FIG. 2).

In FIGS. 2 and 3B, a second one of source/drain regions 108 of the transistor PG_{L} is electrically connected to the overlying bit line BLB through a contact 203i. The gate structure G2 of the transistor PG_{L} is electrically connected to the gate structure G2 of the transistor PG_{R} through the contact 203j (see FIG. 3B), and the gate structures G2 of the transistors PG_{R} and PG_{R} are electrically connected to the overlying word line WL through the contact 203k. A second one of source/drain regions 108 of the transistor PG_{R} is electrically connected to the overlying bit line BL through a contact 203m. A second one of the source/drain regions 108 of the transistor nRP₁ is electrically connected to a first source/drain node of the transistor nRP₂. In some embodiments, the transistor nRP₁ and the transistor nRP₂ can share the same source/drain region 108. A second one of the source/drain regions 108 of the transistor nRP₂ is electrically connected to the overlying read bit line nRBL through a contact 203n, and the gate structure G2 of the transistor nRP₂ is electrically connected to the overlying read word line nRWL through a contact 2030 (see FIG. 3B) and a contact 203p (see FIGS. 2 and 3B).

As shown in FIGS. 2-3B, a footprint of the transistor nRP₁ can overlap with a footprint of the transistor pRP₁, and a footprint of the transistor nRP₂ can overlap with a footprint of the transistor pRP₂. In some embodiments, a footprint of a transistor is a vertical projection of the transistor on a substrate. In some embodiments, a footprint of the transistor nRP₁ can overlap with a footprint of the transistor pRP₂, and a footprint of the transistor nRP₂ can overlap with a footprint of the transistor pRP₁. A footprint of the transistors PD_{L} can overlap with a footprint of the first write transistor PU_{L}, and a footprint of the transistors PD_{R} can overlap with a footprint of the first write transistor PU_{R}. On the other hand, footprints of the channel layers 202 of the transistor nRP₁ and nPR2 can overlap with footprints of the channel layers 102 of the transistor pRP₁ and pPR2. Footprints of the channel layers 202 of the transistors PD_{L} and PD_{R} can overlap with footprints of the transistor PU_{L} and PU_{R}.

In some embodiments, the voltage source line VDD-1/VDD-2 and/or the ground line VSS-1/VSS-2 can be interchangeable referred to as a backside power line. In some embodiments, the voltage source lines VDD-1 and VDD-2 and ground lines VSS-1 and VSS-2 can be collectively referred to a backside power delivery network (BSPDN). In some embodiments, by integrating backside power delivery network and complementary FET technologies, the implementation of the multi-port CFET SRAM can have a reduction in routing complexity. This approach not only streamlines the internal architecture of the SRAM cell 10 but also enhances overall circuit efficiency and reliability. In some embodiments, the voltage source lines VDD-1 and VDD-2 and the ground lines VSS-1 and VSS-2 can be positioned at back end of line (BEOL) over a front-side of the SRAM cell 10.

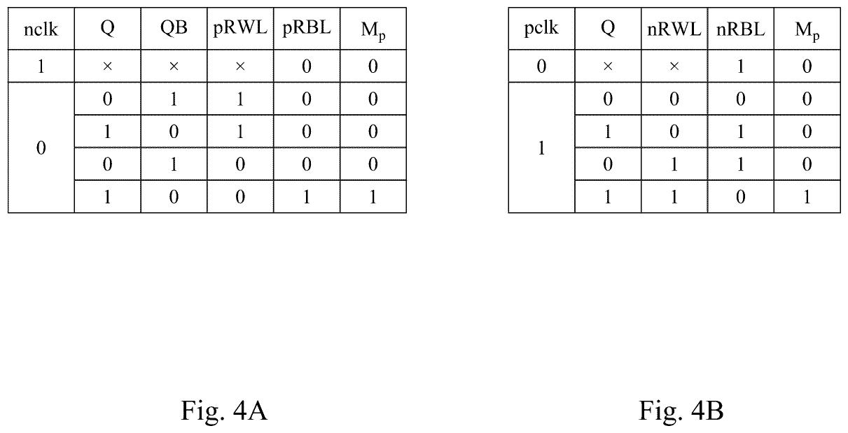

Reference is made to FIGS. 4A and 4B. FIGS. 4A and 4B illustrate tables of operation of a semiconductor structure in accordance with some embodiments of the present disclosure. Specifically, the pre-charge state is a step in preparing the SRAM bit cell 10 for read operations. The pre-charge state can include setting the bit lines pRBL and nRBL to predefine levels to ensure that the read operation can accurately interpret the stored data. The pre-charge state can be achieved by manipulating clock signals nclk and pclk, which control the pre-discharge of the bit line pRBL and the charging of the bit line nRBL, respectively. In FIG. 4A, as show in row 1 of the table, when the clock signal nclk is set to ‘1’, the transistor M1 of the pre-discharge circuit 12b connected to the bit line pRBL can be activated. The pre-discharge circuit 12b can discharge the bit line pRBL to a ground voltage GND (e.g., ground, low voltage level, or zero voltage level), leading to the output signal Mp being at the low voltage state (or ‘0’) and ensuring the bit line pRBL can start from the low voltage state before read operation. On the other hand, in FIG. 4B, as show in row 1 of the table, when the clock signal pclk is set to ‘0’, the transistor M4 of the pre-charge circuit 12b connected to nRBL can be activated. The pre-charge circuit 12b can charge the bit line nRBL to the supply voltage VDD (e.g., high voltage level), which can be a positive supply voltage level, leading to the output signal Mn being at the low voltage state (or ‘0’) and ensuring bit line nRBL can start from a high voltage state before the read operation begins for the subsequent differentiation between a stored ‘l’ and ‘O’ during the read operation.

In some embodiments, the pre-discharge circuit 12b can incorporate a combination of two n-type field-effect transistors (nFETs) and an inverter alongside two p-type field-effect transistors (pFETs) and an inverter. In some embodiments, the pre-charge circuit 14b can incorporate a combination of two nFETs and an inverter alongside two pFETs and an inverter. These configurations in the pre-discharge circuit 12b and the pre-charge circuit 14b can ensures robust and efficient charging and discharging mechanisms within the SRAM bit cell 10, optimizing performance for various operational needs. In some embodiments, the SRAM cell 10 may incorporate an inverter N1 situated at the output of read port 12a. Alternatively, the SRAM cell 10 might omit this inverter N1. Similarly, the SRAM cell 10 may incorporate an inverter N2 situated at the output of read port 14a. Alternatively, the SRAM cell 10 might omit this inverter N2. These variations can offer flexibility in the output signal processing at the read ports 12a and 14a, catering to different application requirements.

In the operation of the read port 12a, as shown in FIG. 4A, when the clock signal nclk is set to ‘0’ with the transistor M1 of the pre-discharge circuit 12b turned off, the bit line pRBL can be a floating state at ‘0’, which is a transitional state awaiting further action or stabilization. If the bit line pRBL remains floating at ‘O’ with the word line pRWL being at a high voltage level (‘1’), indicating the transistor pRP₂ turned off, the output signal Mp remains at the low voltage state (‘0’). If the bit line pRBL remains floating at ‘0’ with the word line pRWL being at the low voltage level (‘0’), indicating the transistor pRP₂ turned on, and if the storage node QB is at a high voltage level (‘1’), indicating the transistor pRP₁ turned off, the output signal Mp remains at the low voltage state (‘0’). When the bit line pRBL connects to the supply voltage VDD, turning it to ‘1’, with the word line pRWL being at the low voltage level (‘0’), indicating the transistor pRP₂ turned on, and if storage node QB is at a low voltage level (‘0’), indicating the transistor pRP₁ turned on, the output signal Mp switches to ‘1’.

In the operation of the read port 14a as shown in FIG. 4B, when the clock signal nclk is set to ‘1’ with the transistor M4 of the pre-charge circuit 14b turned off, the bit line nRBL can be a floating state at ‘1’, which is a transitional state awaiting further action or stabilization. If the bit line nRBL remains floating at ‘1’ with the word line nRWL being at a low voltage level (‘0’), indicating the transistor nRP₂ turned off, the output signal Mn remains at the low voltage state (‘0’). If the bit line nRBL remains floating at ‘1’ with the word line nRWL being at a high voltage level (‘1’), indicating the transistor nRP₂ turned on, and if the storage node Q is at a low voltage level (‘0’), indicating the transistor nRP₁ turned off, the output signal Mn remains at the low voltage state (‘0’). When the bit lien nRBL connects to the ground voltage GND, turning it to ‘0’, with the word line nRWL being at the high voltage level (‘1’), indicating the transistor nRP₂ turned on, and if the storage node Q is at the voltage level (‘1’), indicating the transistor nFET nRP₁ turned on, the output signal Mn switches to ‘1’.

The write operation of the SRAM bit cell 10 can ensure data is stored within the SRAM bit cell 10. The SRAM bit cell 10 includes of six transistors (i.e., transistors PU_{L}, PU_{R}, PD_{L}, PD_{R}, PG_{L}, and PG_{R}): two cross-coupled inverters (e.g., transistors PU_{L}, PU_{R}, PD_{L}, and PD_{R}) that maintain the stored bit and two additional transistors (e.g., transistors PG_{L} and PG_{R}) that act as access gates to the cell. The cross-coupled inverters can create a structure that holds a bit of data (i.e., either ‘0’ or ‘1’), while the access gates controlled by the word line WL allow for data to be written into or read from the SRAM bit cell 10. To initiate a write operation, the word line WL can activated (i.e., set high voltage level), which turns on the access transistors (e.g., transistors PG_{L} and PG_{R}), which in turn connects the internal storage nodes Q and QB of the SRAM bit cell 10 to the bit lines BL and BLB. The data to be written into the SRAM bit cell 10 can be applied to the bit lines BL and BLB. One bit line BL can carry the data value, while the complementary bit line BLB can carry the inverse of that value. For example, to write ‘l’ into the SRAM bit cell 10, the bit line BL would be set to a high voltage level (e.g., supply voltage VDD), and the bit line BLB, vice versa to write a ‘0’, would be set to a low voltage level (e.g., ground voltage GND).

Additionally, the Multiply-and-Accumulate (MAC) operation is an arithmetic operation used in digital signal processing (DSP), neural networks, and various computing tasks requiring repetitive multiplication and addition. While SRAM bit cells 10 is used for data storage, discussing MAC operations in the SRAM bit cells 10 can involve understanding how SRAM bit cells 10 could be utilized or influenced in a system performing MAC operations. In some embodiments, if the read word line is set to be activated (‘1’) for the MAC operation, then the word line nRWL is set to be activated (‘1’) and the word line pRWL is set to be deactivated (‘0’). In some embodiments, if the read word line is set to be deactivated (‘0’) for the MAC operation, then the word line nRWL is set to be deactivated (‘0’) and the word line pRWL is set to be activated (‘1’).

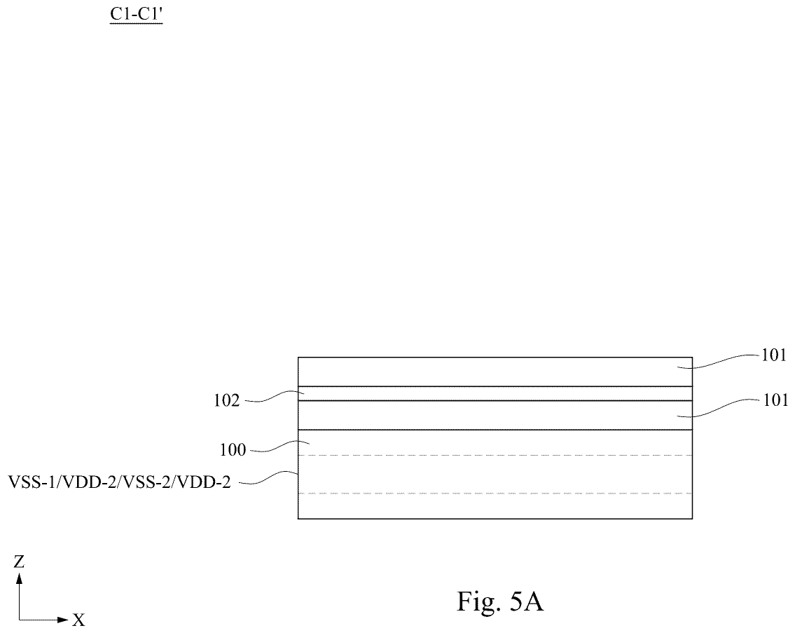

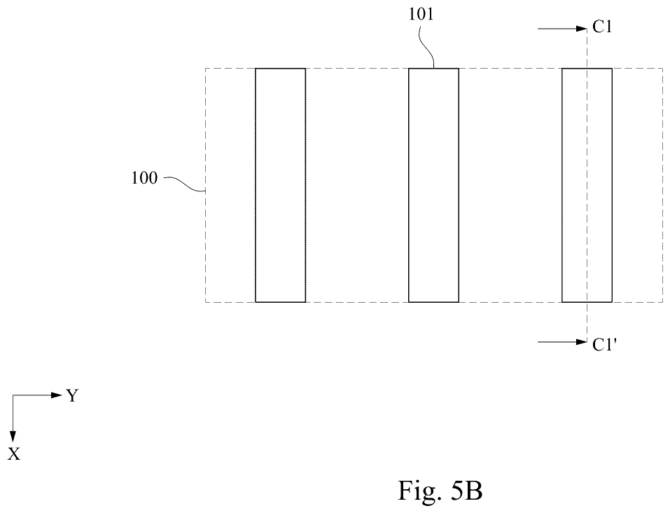

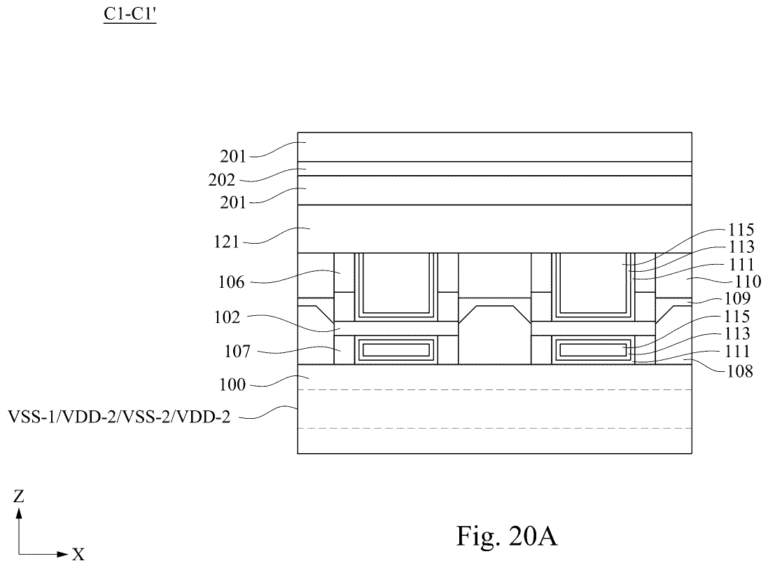

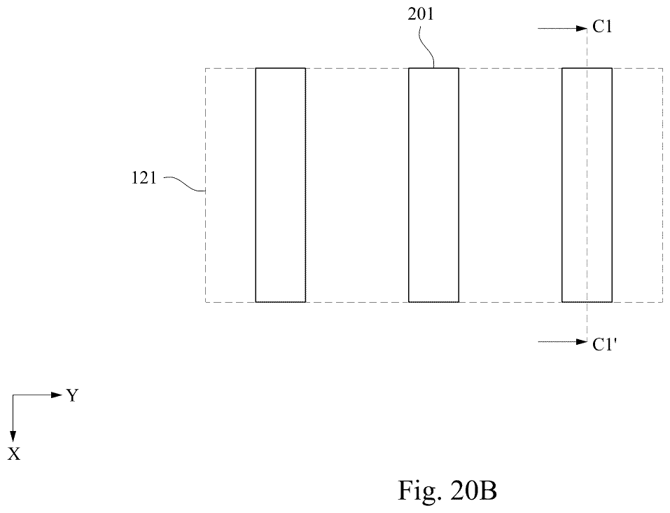

Reference is made to FIGS. 5A-33. FIGS. 5A, 6-20A, and 21-33 illustrate cross-sectional views of intermediate stages obtained from the reference cross-section C1-C1′ in the formation of the semiconductor structure in accordance with some embodiments. FIGS. 5B and 20B illustrate top views of the semiconductor structure corresponding to FIGS. 5A and 20A in accordance with some embodiments. It is understood that additional operations can be provided before, during, and after the processes shown by FIGS. 5A-33, and some of the operations described below can be replaced or eliminated, for additional embodiments of the method. The order of the operations/processes may be interchangeable.

Reference is made to FIGS. 5A and 5B. An epitaxial stack is formed over a substrate 100. In some embodiments, the substrate 100 may include silicon (Si). Alternatively, the substrate 100 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 100 may include a semiconductor-on-insulator (SOI) structure such as a buried dielectric layer. Also alternatively, the substrate 100 may include a buried dielectric layer such as a buried oxide (BOX) layer, such as that formed by a method referred to as separation by implantation of oxygen (SIMOX) technology, wafer bonding, SEG, or another appropriate method. The substrate 100 may include voltage source lines VDD-1 and VDD-2 and ground lines VSS-1 and VSS-2. In some embodiments, the voltage source lines VDD-1 and VDD-2 and ground lines VSS-1 and VSS-2 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof, and the formation thereof can be performed by any suitable process. The ground lines VSS-1 and VSS-2 and the voltage source lines VDD-1 and VDD-2 can be formed at a same level height.

The epitaxial stack includes sacrificial layers 101 of a first composition interposed by a channel layer 102 of a second composition. The first and second compositions can be different. In some embodiments, the sacrificial layers 101 may be made of SiGe and have a different germanium atomic concentration than the channel layer 102. In some embodiments, the sacrificial layer 101 can have a greater germanium atomic concentration than the channel layer 102. In some embodiments, the channel layer 102 may be made of silicon (Si). By way of example but not limitation, the sacrificial layer 101 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

The use of the channel layer 102 to define a channel or channels of a device is further discussed below. It is noted that one layer of the channel layer 102 is arranged as illustrated in FIG. 5A, which is for illustrative purposes only and not intended to be limiting beyond what is specifically recited in the claims. It can be appreciated that any number of sacrificial layers 101 can be formed in the epitaxial stack; the number of layers depending on the desired number of channels regions for the transistor. In some embodiments, the number of the channel layer 102 can be between about 1 and 100. As described in more detail below, the channel layer 102 may serve as a channel region for a subsequently-formed semiconductor device and the thickness is chosen based on device performance considerations. The sacrificial layers 101 in the channel region may eventually be removed and serve to define a vertical distance between adjacent channel region(s) for a subsequently-formed multi-gate device and the thickness is chosen based on device performance considerations.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the channel layer 102 can include the same material as the substrate 100. In some embodiments, the sacrificial layers 101 and channel layer 102 can include different materials than the substrate 100. As stated above, in at least some examples, the sacrificial layers 101 can include epitaxially grown silicon germanium (SiGe) layers, and the channel layers 102 can include an epitaxially grown silicon (Si) layer. Alternatively, in some embodiments, either of the sacrificial layer 101 and the channel layer 102 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. In some embodiments, the channel layer 102 can include IV-based material, such as Si, Ge, Sn, Si₁₋ₓGeₓ, Ge_{1-y}Sn_{y}, Si_{1-x-y}GeₓSn_{y}, other suitable materials, or combinations thereof. In some embodiments, the channel layer 102 can include III-V-based material, an oxide semiconductor material, 2D (two dimensional) material, other suitable materials, or combinations thereof. As discussed, the materials of the sacrificial layer 101 and the channel layer 102 may be chosen based on providing differing oxidation and/or etching selectivity properties.

Subsequently, the epitaxial stack includes the channel layer 102 and the sacrificial layers 101 can be patterned, such that the channel layer 102 and the sacrificial layers 101 or portions thereof may be formed nanostructures as shown in FIG. 5B. Specifically, the channel layer 102 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layer 102 and the sacrificial layers 101 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer can be formed over the substrate 100 and patterned using a photolithography process. Spacers are formed alongside the patterned sacrificial layer using a self-aligned process. The sacrificial layer is then removed. The etching process can include dry etching, wet etching, reactive ion etching (RIE), and/or other suitable processes.

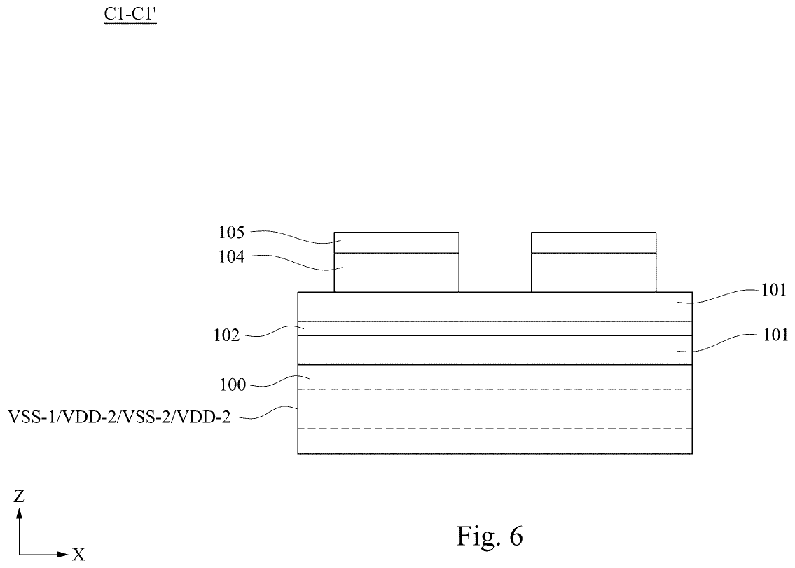

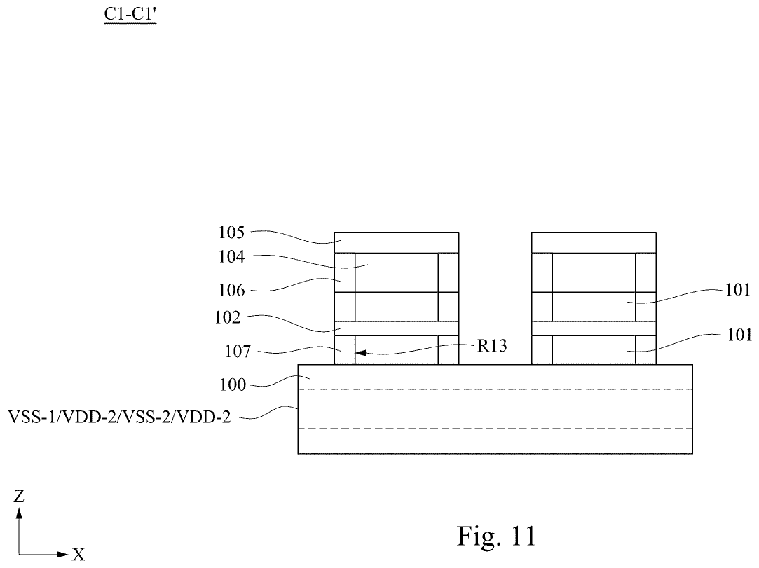

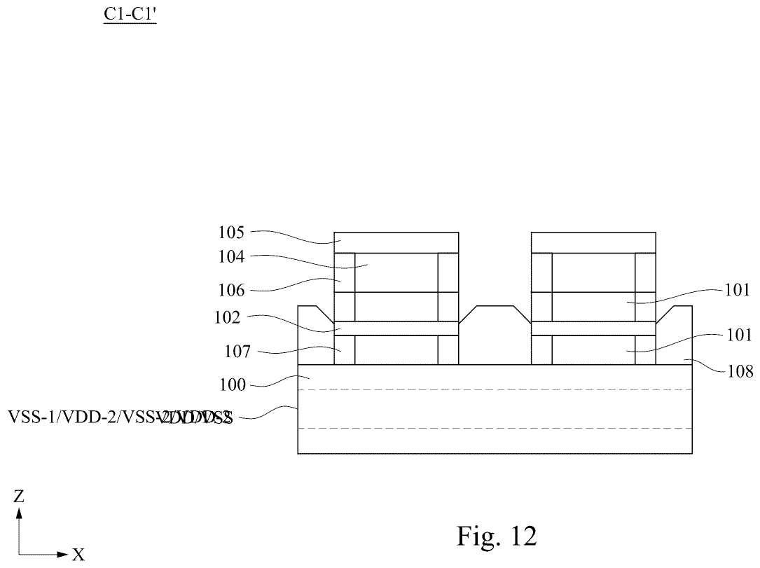

Reference is made to FIG. 6. Dummy gate layers 104 and hard mask layers 105 can be formed over the epitaxial stack as shown in FIG. 6. Portions of the channel layer 102 underlying the dummy gate layers 104 may be referred to as the channel regions. The dummy gate layer 104 may also define source/drain regions 108 (labeled in FIG. 12). Dummy gate formation operation forms the dummy gate layer 104 and the hard mask layer 105 over the dummy gate layer 104. The hard mask layer 105 is then patterned, followed by patterning the dummy gate layer 104 by using the patterned hard mask layer 105 as an etch mask. The etch process may include a wet etch, a dry etch, and/or combinations thereof.

In some embodiments, the dummy gate layer 104 may include polycrystalline-silicon (poly-Si), poly-crystalline silicon-germanium (poly-SiGe), metallic nitrides, metallic silicides, metallic oxides, or metals. In some embodiments, the dummy gate layer 104 may include a metal-containing material such as TiN, TaN, TaC, Co, Ru, Al, combinations thereof, or multi-layers thereof. The hard mask layer 105 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 104 may be deposited by CVD, physical vapor deposition (PVD), sputter deposition, or other techniques suitable for depositing conductive materials. In some embodiments, the hard mask layer 105 may be deposited by CVD, physical vapor deposition (PVD), sputter deposition, or other techniques suitable for depositing conductive materials. In some embodiments, the dummy gate layer 105 can be interchangeably referred to a dummy gate, a dummy gate pattern, a dummy gate strip, an isolation structure, or a dielectric gate.

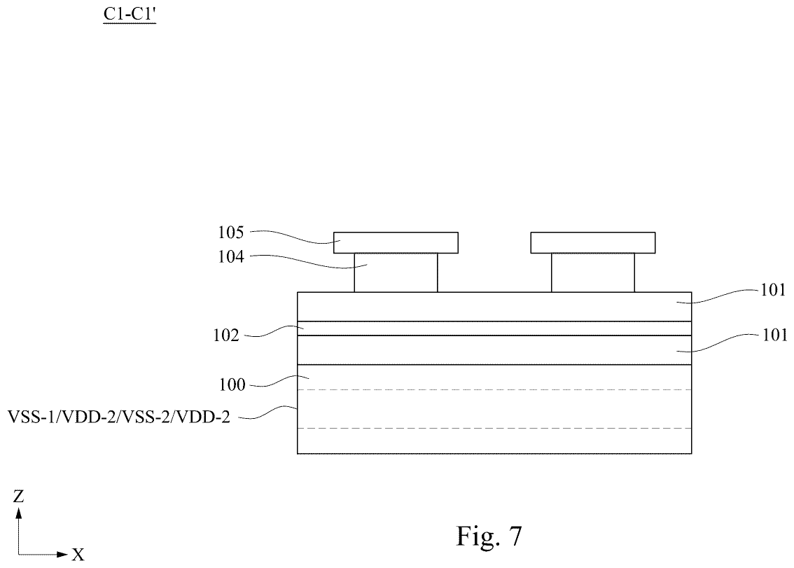

Reference is made to FIG. 7. The dummy gate layer 104 is laterally or horizontally recessed by using suitable etch techniques, resulting in lateral recesses R11 vertically between the sacrificial layer 101 and the hard mask layer 105. This operation may be performed by using a selective etching process. By way of example and not limitation, the sacrificial layer 101 may be made of SiGe, the hard mask layer 105 may be made of a dielectric material and the dummy gate layer 104 may be made of silicon allowing for the selective etching of the dummy gate layer 104. In some embodiments, the selective dry etching etches Si at a faster etch rate than it etches SiGe and the dielectric material. As a result, the sacrificial layer 101 and the hard mask layer 105 laterally extend past opposite end surfaces of the dummy gate layer 104.

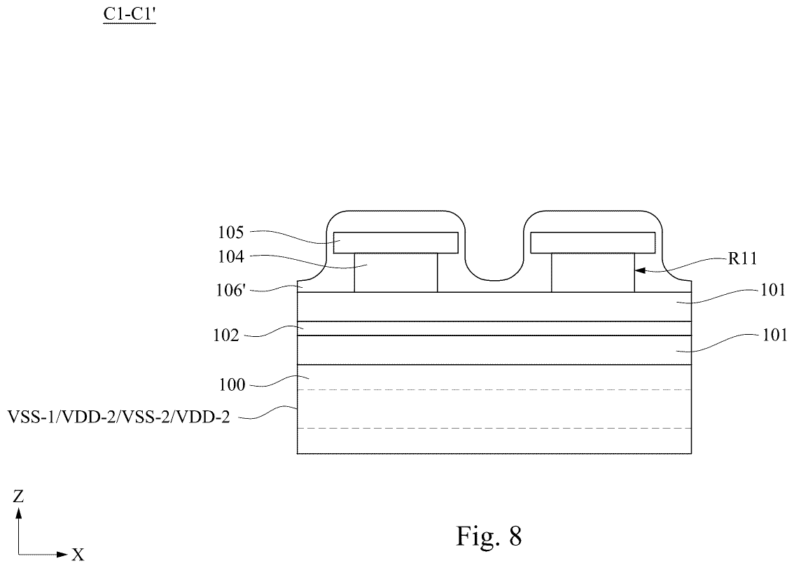

Reference is made to FIG. 8. After recession of the dummy gate layer 104 is completed, a spacer material 106′ is deposited over the substrate 100. The spacer material 106′ may be a conformal layer on the topmost sacrificial layer 101, the dummy gate layers 104, and the hard mask layers 105. The spacer material 106′ may include a dielectric material such as silicon oxide, silicon nitride, silicon carbide, silicon oxynitride, SiCN films, silicon oxycarbide, SiOCN films, and/or combinations thereof. In some embodiments, the spacer material 106′ can include multiple layers, such as a first spacer layer and a second spacer layer formed over the first spacer layer. By way of example, the spacer material 106′ may be formed by depositing a dielectric material over the topmost sacrificial layer 101, the dummy gate layers 104, and the hard mask layers 105 using suitable deposition processes.

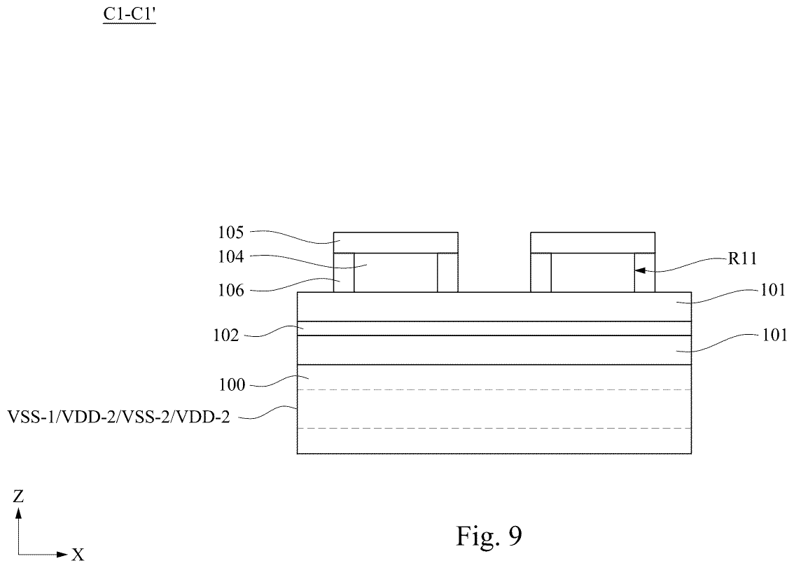

Reference is made to FIG. 9. An anisotropic etching process is then performed on the deposited spacer material 106′ to expose the topmost sacrificial layer 101 and the hard mask layers 105. Portions of the spacer material 106′ directly on the hard mask layers 105 and on the topmost sacrificial layer 101 not covered by the hard mask layers 105 may be completely removed by this anisotropic etching process. Portions of the spacer material 106′ on sidewalls of the recessed dummy gate layer 104 may remain in the lateral recesses R11, forming gate sidewall spacers 106, which are denoted as the gate spacers 106.

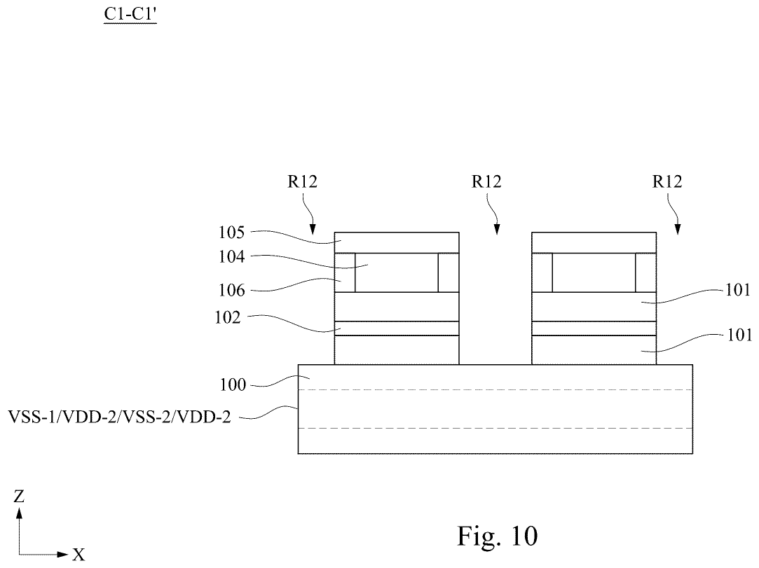

Reference is made to FIG. 10. Exposed portions of the patterned channel layer 102 and the patterned sacrificial layers 101 that extend laterally beyond the gate spacers 106 are etched by using, for example, an anisotropic etching process that uses the dummy gate layer 104 and the gate spacers 106 as an etch mask, resulting in recesses R12 into the channel layers 102 and the sacrificial layers 101. After the anisotropic etching, end surfaces of the patterned channel layer 102 and the patterned sacrificial layers 101 and respective outermost sidewalls of the gate spacers 106 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Reference is made to FIG. 11. The patterned sacrificial layers 101 are laterally or horizontally recessed by using suitable etch techniques, resulting in lateral recesses R13. This operation may be performed by using a selective etching process. By way of example and not limitation, the sacrificial layers 101 can be made of SiGe and the channel layer 102 can be made of silicon allowing for the selective etching of the sacrificial layers 101. In some embodiments, the selective dry etching etches SiGe at a faster etch rate than it etches Si. As a result, the patterned channel layer 102 laterally extend past opposite end surfaces of the patterned sacrificial layers 101.

Subsequently, inner spacers 107 are filled in the recesses R13, respectively. For example, spacer material layers are formed to fill the recesses R13 left by the lateral etching of the sacrificial layers 101 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R13 left by the lateral etching of the sacrificial layers 101 are left. After the trimming process, the remaining portions of the deposited spacer material are denoted as inner spacers 107 in the recesses R13. The inner spacers 107 serve to isolate metal gates from source/drain regions formed in subsequent processing.

Reference is made to FIG. 12. Source/drain regions 108 are formed in the recesses R12 and connected to the channel layer 102. The source/drain regions 108 may be formed by performing an epitaxial growth process that provides an epitaxial material on the substrate 100. During the epitaxial growth process, the dummy gate layer 104, the gate spacers 106, and the inner spacers 107 limit the source/drain regions 108 to the substrate 100 and the channel layer 102. In some embodiments, the lattice constants of the source/drain regions 108 are different from the lattice constant of the channel layer 102, so that the channel layer 102 can be strained or stressed by the source/drain regions 108 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 102.

In some embodiments, the source/drain regions 108 may include Ge, Si, GaAs, AlGaAs, SiGe, GaAsP, SiP, or other suitable material. The source/drain regions 108 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 108 are not in-situ doped, an implantation process (i.e., a junction implant process) is performed to dope the source/drain regions 108. In some embodiments, the source/drain regions 208 can be of a p-type transistor and include SiGeB and/or GeSnB.

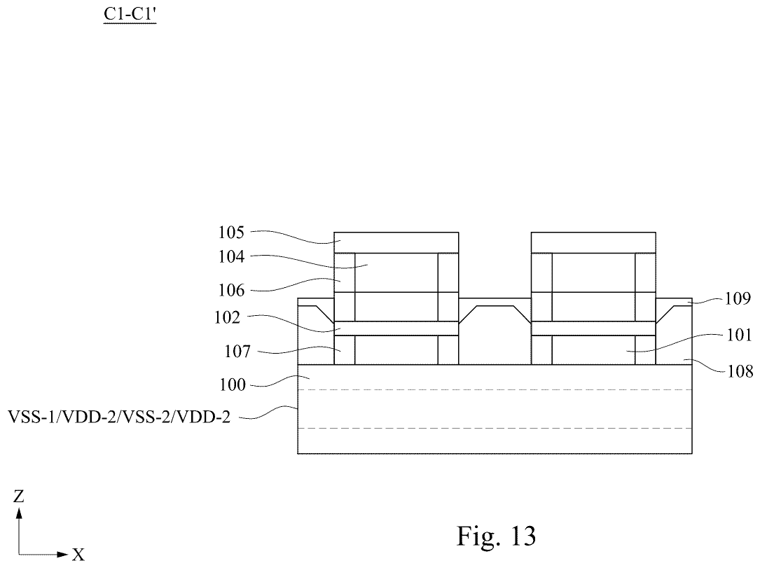

Reference is made to FIG. 13. Source/drain contacts 109 can be formed over the source/drain regions 108. In some embodiments, the source/drain contacts 109 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 109 can be performed by such as a lift-off process. By way of example and not limitation, a mask layer (not shown) can be formed by depositing a photoresist layer over the substrate 100 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 109. Subsequently, a contact material can be deposited over the substrate 100 and formed on the source/drain contacts 109 and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 108 are remained to form the source/drain contacts 109.

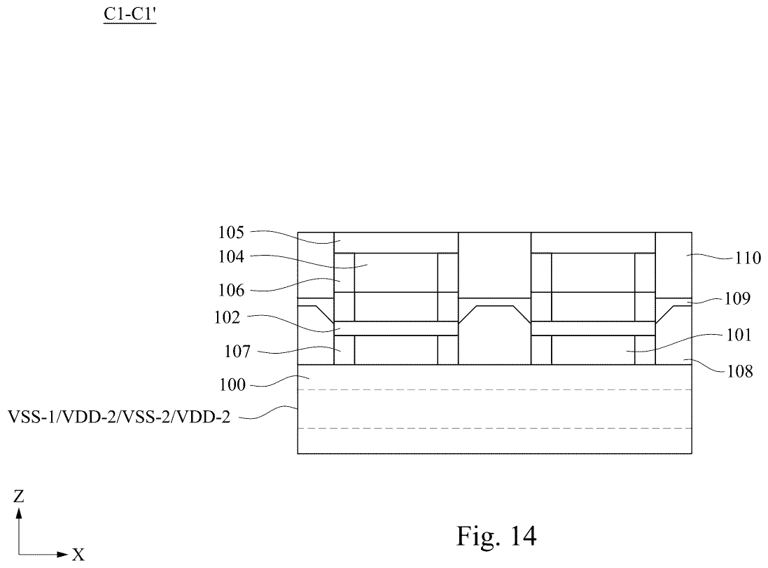

Reference is made to FIG. 14. An ILD layer 110 is formed over the substrate 100. In some embodiments, the ILD layer 110 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 110 may be deposited by a plasma-enhanced chemical vapor deposition (PECVD) process or other suitable deposition technique. In some embodiments, after formation of the ILD layer 110, the substrate 100 may be subject to a high thermal budget process to anneal the ILD layer 110. Subsequently, a planarization process (e.g., CMP) is performed to remove the excessive ILD layer 110 until the hard mask layer 105 is exposed. In some embodiments, the hard mask layer 105 may also act as an etch stop layer for etching the ILD layer 110.

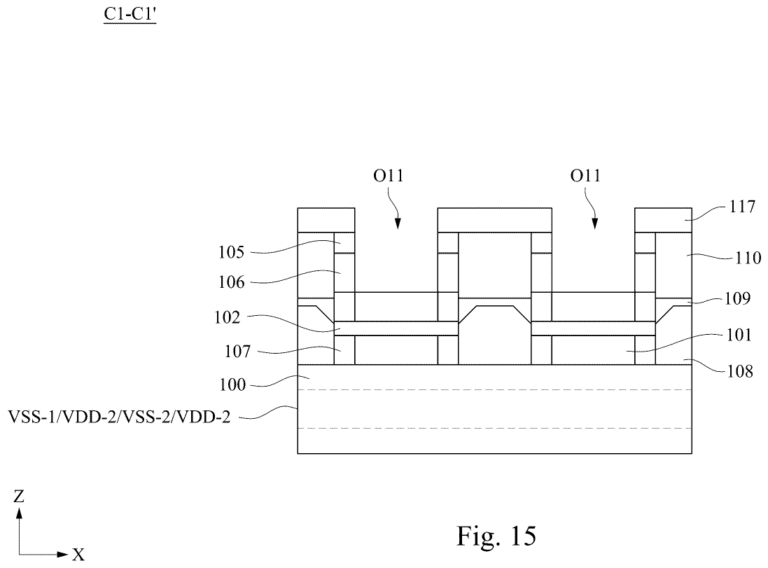

Reference is made to FIG. 15. A hard mask layer 117 may be formed over the ILD layer 110 and the hard mask layer 105. In some embodiments, the hard mask layer 117 may be made of the same material as the ILD layer 110, thereby resulting in a substantially indistinguishable interface between the hard mask layer 117 and the ILD layer 110. In some embodiments, the hard mask layer 117 may be made of a different material than the ILD layer 110b. In some embodiments, the hard mask layer 117 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 117 can be performed by using any suitable method, such as CVD, physical vapor deposition (PVD), ALD, PEALD, PECVD, SACVD, FCVD, spin-on, and/or the like, or a combination thereof. Subsequently, the hard mask layer 117 is patterned and then be used to etch the dummy gate layer 104 (see FIG. 14), the hard mask layer 105, and the ILD layers 110. The hard mask layer 117 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 117, the dummy gate layer 104 (see FIG. 14), the hard mask layer 105, and the ILD layer 110 can be etched through the patterned hard mask layer 117 to form an opening O11. The opening O11 can expose a sidewall of the epitaxial stack, such that the channel layer 102 and the sacrificial layers 101 can be exposed from the opening O11. The etching process may include dry etching, wet etching, and/or other etching methods (e.g., reactive ion etching). In some embodiments, the opening O11 may have a rectangular profile extending along Y-direction from the top view. After the formation of the opening O11, the patterned mask can be removed by a suitable technique, such as a wet clean process, an ashing process, or the like.

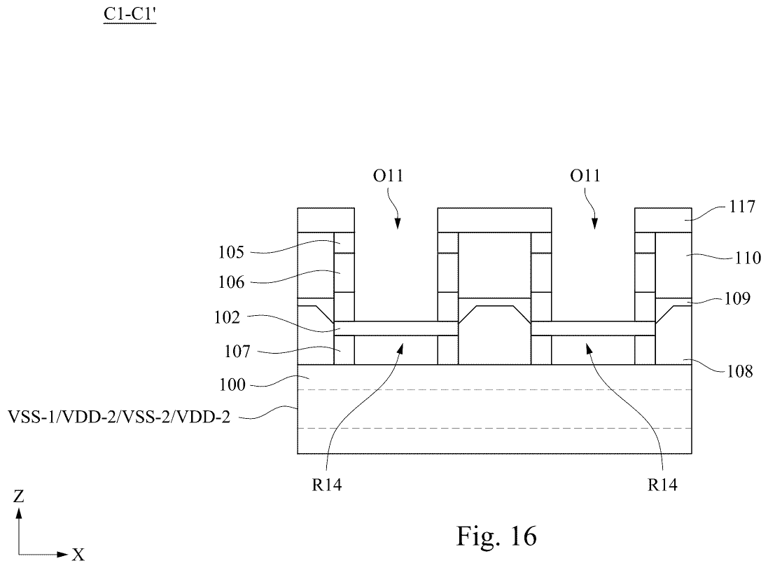

Reference is made to FIG. 16. The sacrificial layers 101 (see FIG. 15) are removed in one or more etching process, so that a recess R14 can be formed to inherit the shape of a lower one of the sacrificial layers 101. The recess R14 can expose a bottom surface of the channel layer 102, and the opening O11 can expose a top surface of the channel layer 102. In some embodiments, the sacrificial layers 101 can be removed by an anisotropic dry etch process. For example, the etching process may include a dry etch process using reaction gas(es) that selectively etch the sacrificial layers 101 at faster rates than the substrate 100, the ILD layer 110, and the channel layer 102.

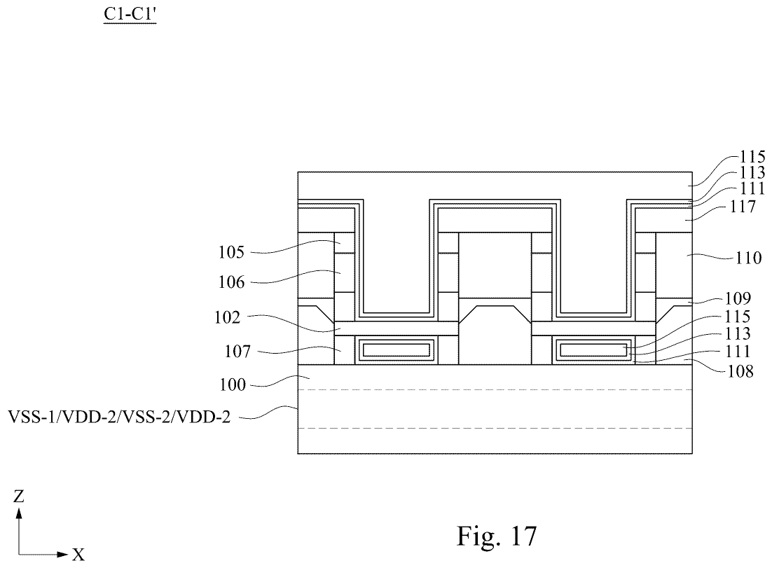

Reference is made to FIG. 17. An interfacial layer 111 and a high-k dielectric layer 113 can be conformally formed over the hard mask layer 117 and in the opening O11 and the recesses R14. In some embodiments, the interfacial layer 111 may include a dielectric material such as silicon oxide (SiO₂), HfSiO, or silicon oxynitride (SiON). In some embodiments, the interfacial layer 111 may be deposited using any suitable method, such as CVD, physical vapor deposition (PVD), ALD, PEALD, PECVD, SACVD, FCVD, spin-on, and/or the like, or a combination thereof. In some embodiments, the high-k dielectric layer 113 may include high-k dielectric material, such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 113 may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 115 can be deposited over the high-k dielectric layer 113. The gate electrode layer 115 may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

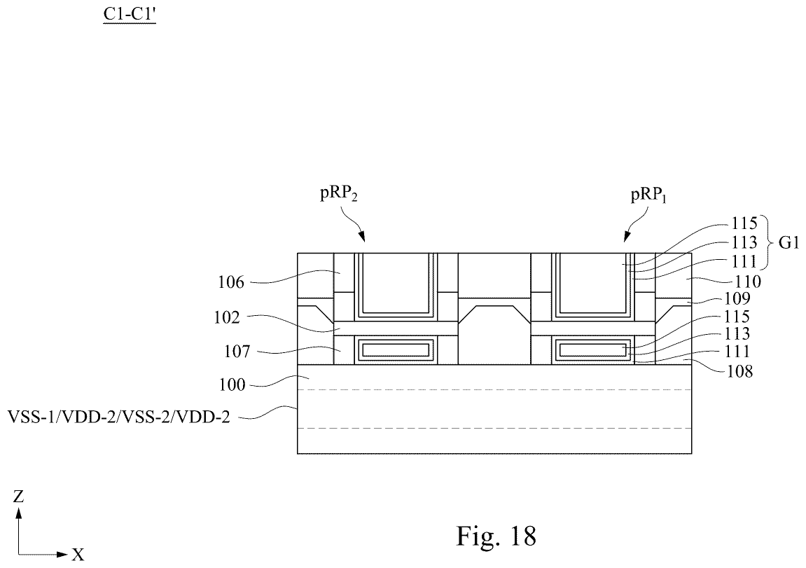

Reference is made to FIG. 18. A planarization process (e.g., CMP) is performed to remove the excessive gate electrode layer 115, the high-k dielectric layer 113, the interfacial layer 111, and the hard mask layers 105 and 117 above the gate spacers 106. The gate spacers 106 may also act as an etch stop layer for etching the gate electrode layer 115, the high-k dielectric layer 113, the interfacial layer 111, and the hard mask layers 105 and 117. Therefore, a (metal) gate structure G1 including the gate electrode layer 115, the high-k dielectric layer 113, and the interfacial layer 111 can be formed in the recesses R14 to surround the channel layer 102 suspended in the recesses R14. In some embodiments, the gate structure G1 may be the final gate of a GAA FET.

Therefore, the semiconductor structure can include transistors pRP₁ and pRP₂ (see FIG. 18) and transistors PU_{R}, and PU_{L} (see FIGS. 2, 3A, 3C, and 3D). The transistors pRP₁, pRP₂, PU_{R}, and PU_{L} each includes the channel layer 102, the source/drain regions 108 on opposite sides of the channel layer 102 and connected to the channel layer 102, and the gate structure G1 wrapping around the channel layer 102. In some embodiments, the transistors pRP₁, pRP₂, PU_{R}, and PU_{L} can be interchangeably referred to as bottom-tier transistors. In some embodiments, the transistors pRP₁, pRP₂, PU_{R}, and PU_{L} may be p-type transistors. In some embodiments, the transistors pRP₁, pRP₂, PU_{R}, and PU_{L} may be n-type transistors.

In some embodiments, the contact 103a, 103b, 103c, 103d, 103e, 103f and/or 103g may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof, and the formation thereof can be performed by any suitable process. In some embodiments, the contact 103a, 103b, 103c, 103d, 103e, 103f and/or 103g can be interchangeably referred to as a contact structure, a metal contact, a conductive contact, interconnect structure, a metal interconnect, or a conductive interconnect.

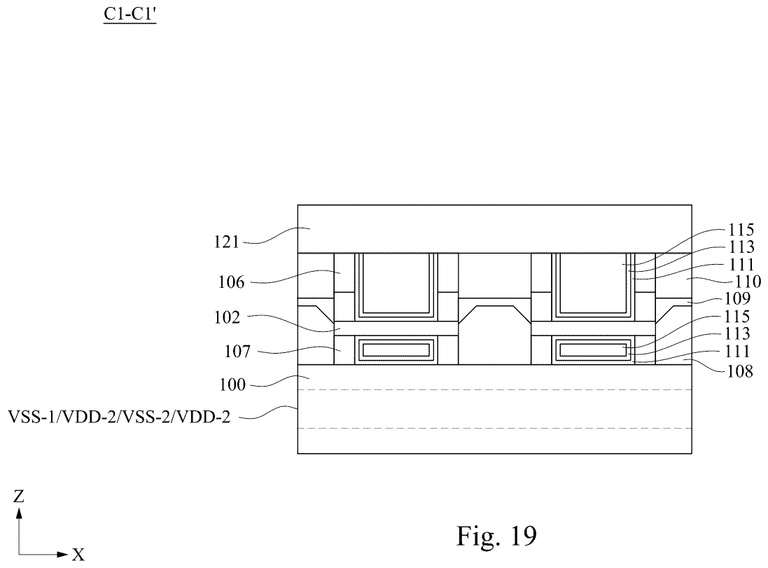

Reference is made to FIG. 19. A MEOL layer 121 can be formed over the transistors pRP₁, pRP₂, PU_{R}, and PU_{L}. The MEOL layer 121 may include an inter-metal dielectric and conductive interconnect to connect the transistors pRP₁, pRP₂, PU_{R}, and PU_{L} to the overlying features (e.g., transistors nRP₁, nRP₂, PG_{R}, PG_{L}, PD_{R}, and PD_{L}). In some embodiments, the inter-metal dielectric may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the conductive interconnect formed in the inter-metal dielectric can be made of tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

Reference is made to FIGS. 20A and 20B. An epitaxial stack is formed over the MEOL layer 121. The epitaxial stack includes sacrificial layers 201 of a first composition interposed by a channel layer 202 of a second composition. The first and second compositions can be different. In some embodiments, the sacrificial layers 201 may be made of SiGe and have a different germanium atomic concentrations than the channel layer 202. In some embodiments, the channel layer 201 may be made of silicon (Si). In some embodiments, the sacrificial layer 201 has a greater germanium atomic concentration than the channel layer 202. By way of example but not limitation, the sacrificial layer 201 may have a germanium atomic concentration in a range from about 10 to 90%, such as about 10, 20, 30, 40, 50, 60, 70, 80, 90%. However, other embodiments are possible including those that provide for the first and second compositions having different etch selectivity.

The use of the channel layer 202 to define a channel or channels of a device is further discussed below. It is noted that one layer of the channel layer 202 is arranged as illustrated in FIG. 20A, which is for illustrative purposes only and not intended to be limiting beyond what is specifically recited in the claims. It can be appreciated that any number of sacrificial layers can be formed in the epitaxial stack; the number of layers depending on the desired number of channels regions for the transistor. In some embodiments, the number of the channel layer 202 can be between about 1 and 100. As described in more detail below, the channel layer 202 may serve as a channel region for a subsequently-formed semiconductor device and the thickness is chosen based on device performance considerations. The sacrificial layer 201 in the channel region may eventually be removed and serve to define a vertical distance between adjacent channel region(s) for a subsequently-formed multi-gate device and the thickness is chosen based on device performance considerations.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the sacrificial layers 201 and channel layer 202 can include different materials than the substrate 100. As stated above, in at least some examples, the sacrificial layers 201 can include epitaxially grown silicon germanium (SiGe) layers, and the channel layer 202 can include an epitaxially grown silicon (Si) layer. Alternatively, in some embodiments, either of the sacrificial layers 201 and the channel layer 202 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the sacrificial layers 201 and the channel layer 202 may be chosen based on providing differing oxidation and/or etching selectivity properties.

Subsequently, the epitaxial stack includes the channel layer 202 and the sacrificial layers 201 can be patterned, such that the channel layer 202 and the sacrificial layers 201 or portions thereof may be formed nanostructures as shown in FIG. 20B. Specifically, the channel layer 102 may be formed nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The patterned channel layers 202 and the sacrificial layers 201 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer can be formed over the MEOL layer 121 and patterned using a photolithography process. Spacers are formed alongside the patterned sacrificial layer using a self-aligned process. The sacrificial layer is then removed. The etching process can include dry etching, wet etching, reactive ion etching (RIE), and/or other suitable processes.

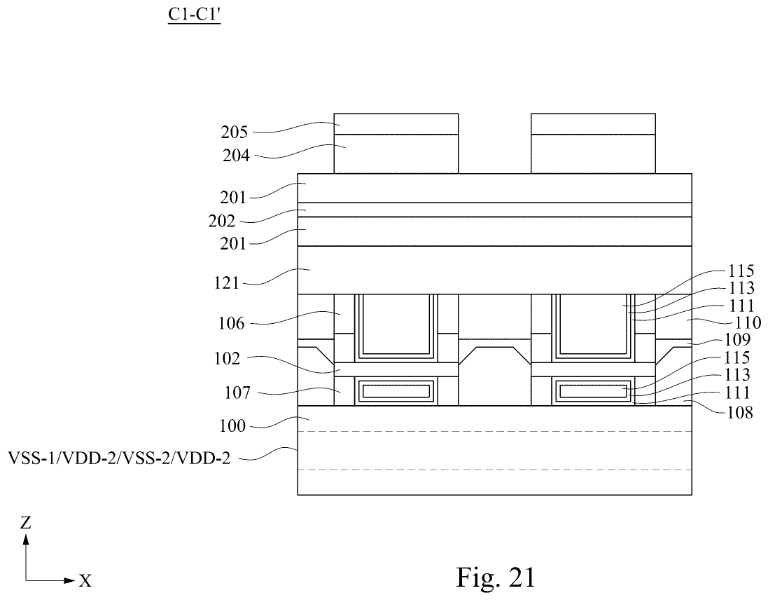

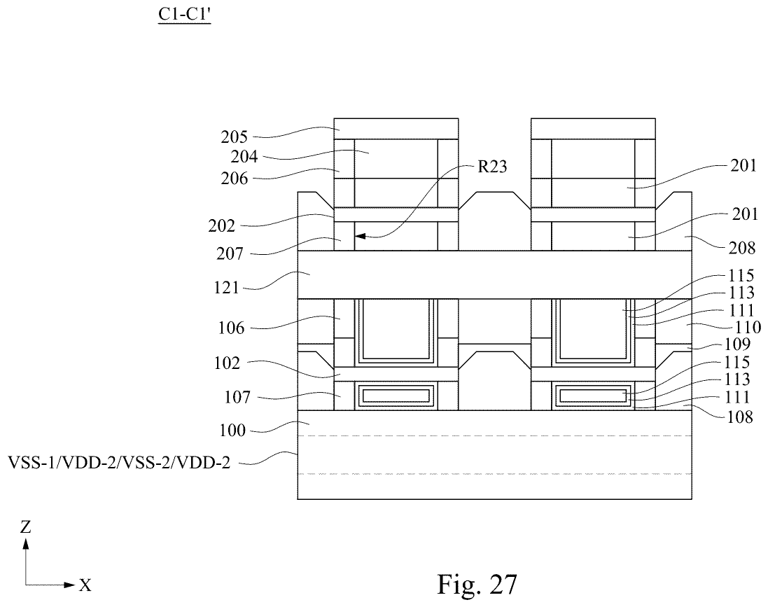

Reference is made to FIG. 21. Dummy gate layers 204 and hard mask layers 205 are formed over the epitaxial stack. Portions of the channel layer 202 underlying the dummy gate layers 204 may be referred to as the channel regions. The dummy gate layer 204 may also define source/drain regions 208 (see FIG. 27). Dummy gate formation operation forms the dummy gate layer 204 and the hard mask layer 205 over the dummy gate layer 204. The hard mask layer 205 is then patterned, followed by patterning the dummy gate layer 204 by using the patterned hard mask layer 205 as an etch mask. The etch process may include a wet etch, a dry etch, and/or combinations thereof.

In some embodiments, the dummy gate layer 204 may include polycrystalline-silicon (poly-Si), poly-crystalline silicon-germanium (poly-SiGe), metallic nitrides, metallic silicides, metallic oxides, or metals. In some embodiments, the dummy gate layer 204 may include a metal-containing material such as TiN, TaN, TaC, Co, Ru, Al, combinations thereof, or multi-layers thereof. The hard mask layer 205 may be made of a dielectric material such as silicon nitride (SiN), silicon oxide (SiO₂), silicon carbo-nitride (SiCN), silicon oxynitride (SiON), silicon oxy-carbon (SiOC), or the like, and may have a single-layer structure or a multi-layer structure including a plurality of dielectric layers. In some embodiments, the dummy gate layer 204 may be deposited by CVD, physical vapor deposition (PVD), sputter deposition, or other techniques suitable for depositing conductive materials. In some embodiments, the hard mask layer 205 may be deposited by CVD, physical vapor deposition (PVD), sputter deposition, or other techniques suitable for depositing conductive materials. In some embodiments, the dummy gate layer 205 can be interchangeably referred to a dummy gate, a dummy gate pattern, a dummy gate strip, an isolation structure, or a dielectric gate.

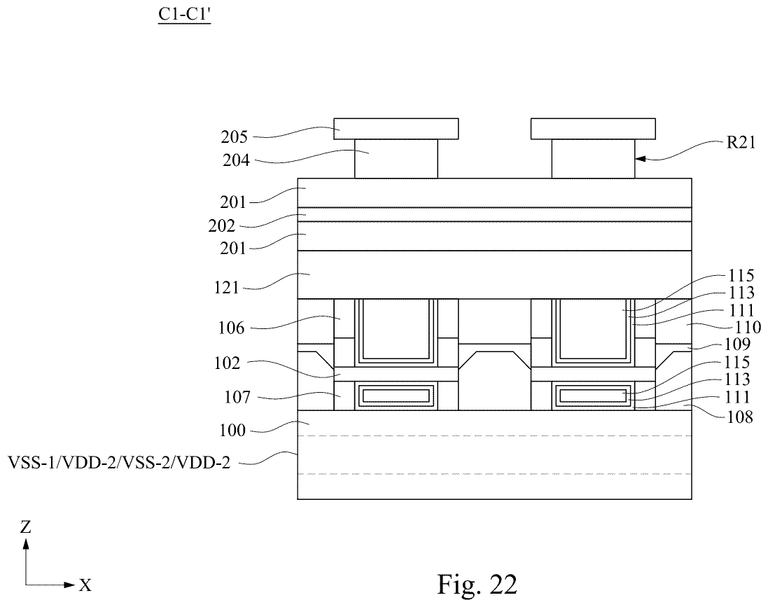

Reference is made to FIG. 22. The dummy gate layer 204 is laterally or horizontally recessed by using suitable etch techniques, resulting in lateral recesses R21 vertically between the sacrificial layer 201 and the hard mask layer 205. This operation may be performed by using a selective etching process. By way of example and not limitation, the sacrificial layer 201 may be made of SiGe, the hard mask layer 205 may be made of a dielectric material, and the dummy gate layer 204 may be made of silicon allowing for the selective etching of the dummy gate layer 204. In some embodiments, the selective dry etching etches Si at a faster etch rate than it etches SiGe and the dielectric material. As a result, the sacrificial layer 201 and the hard mask layer 205 laterally extend past opposite end surfaces of the dummy gate layer 204.

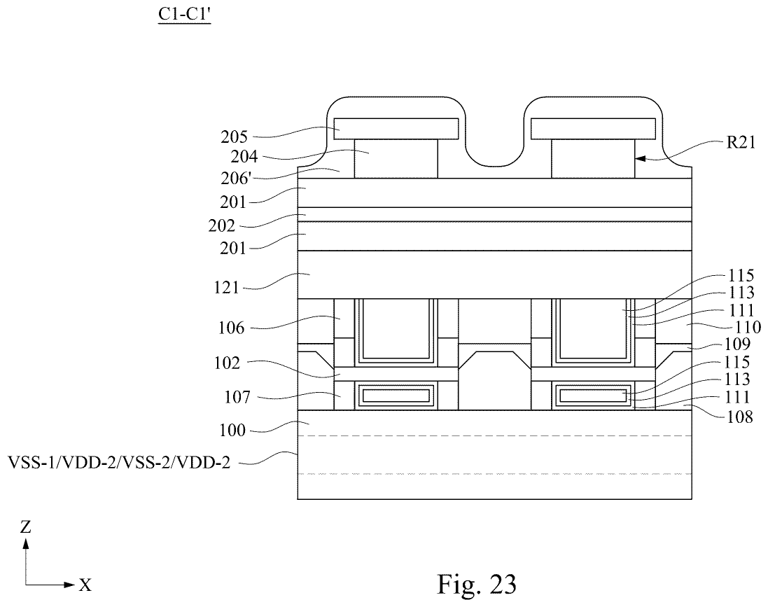

Reference is made to FIG. 23. After recession of the dummy gate layer 204 is completed, a spacer material 206′ is deposited over the MEOL layer 121. The spacer material 206′ may be a conformal layer on the topmost sacrificial layer 201, the dummy gate layers 204, and the hard mask layers 205. The spacer material 206′ may include a dielectric material such as silicon oxide, silicon nitride, silicon carbide, silicon oxynitride, SiCN films, silicon oxycarbide, SiOCN films, and/or combinations thereof. In some embodiments, the spacer material 206′ includes multiple layers, such as a first spacer layer and a second spacer layer formed over the first spacer layer. By way of example, the spacer material 206′ may be formed by depositing a dielectric material over the topmost sacrificial layer 201, the dummy gate layers 204, and the hard mask layers 205 using suitable deposition processes.

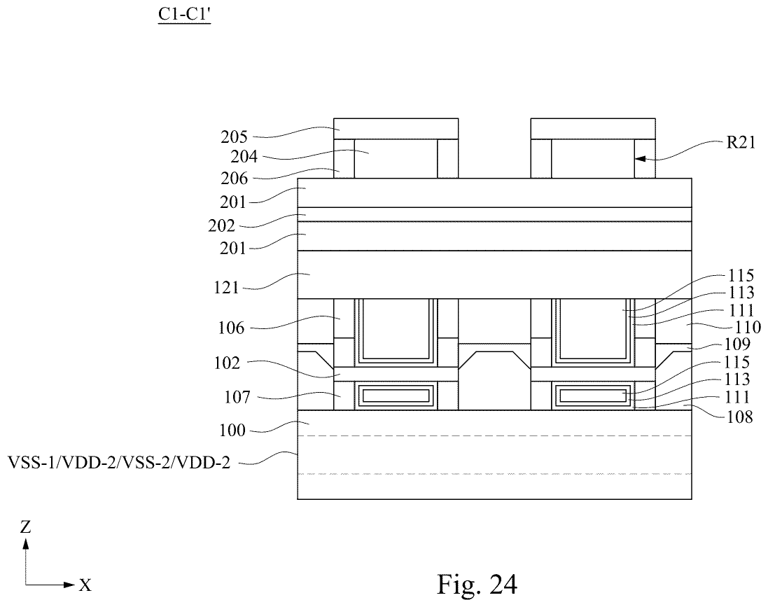

Reference is made to FIG. 24. An anisotropic etching process is then performed on the deposited spacer material 206′ to expose the topmost sacrificial layer 201 and the hard mask layers 205. Portions of the spacer material 206′ directly on the hard mask layers 205 and on the topmost sacrificial layer 201 not covered by the hard mask layers 205 may be completely removed by this anisotropic etching process. Portions of the spacer material 206′ on sidewalls of the recessed dummy gate layer 204 may remain in the lateral recesses R21, forming gate sidewall spacers 206, which are denoted as the gate spacers 206.

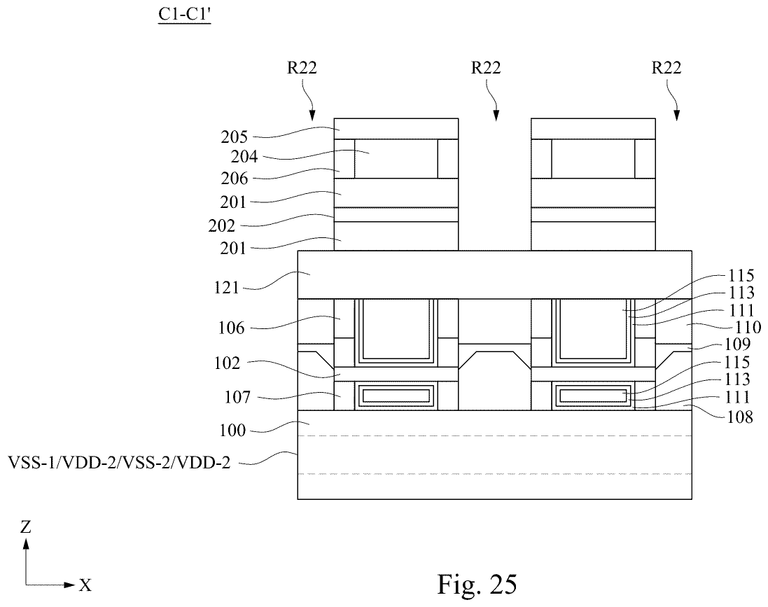

Reference is made to FIG. 25. Exposed portions of the patterned channel layer 202 and the patterned sacrificial layers 201 that extend laterally beyond the gate spacers 206 are etched by using, for example, an anisotropic etching process that uses the dummy gate layer 204 and the gate spacers 206 as an etch mask, resulting in recesses R22 into the channel layer 202 and the sacrificial layers 201. After the anisotropic etching, end surfaces of the patterned channel layer 202 and the patterned sacrificial layers 201 and respective outermost sidewalls of the gate spacers 206 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

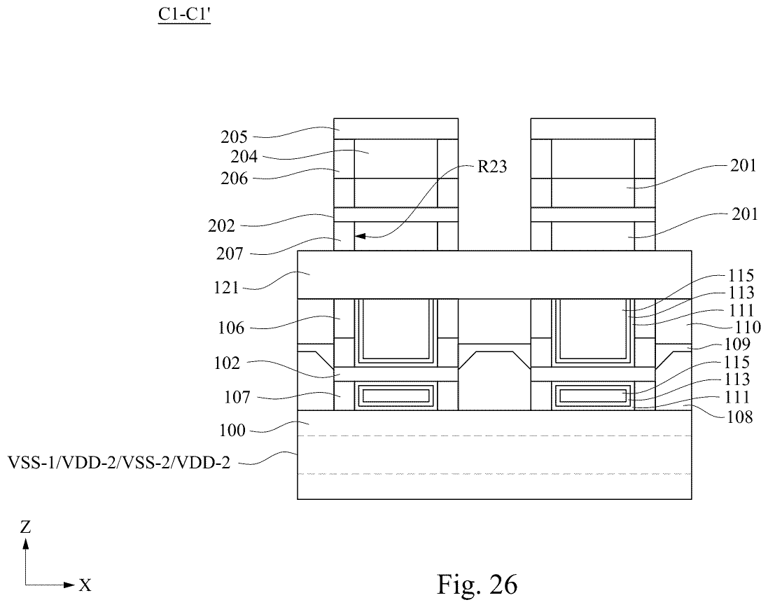

Reference is made to FIG. 26. The patterned sacrificial layers 201 are laterally or horizontally recessed by using suitable etch techniques, resulting in lateral recesses R23. This operation may be performed by using a selective etching process. By way of example and not limitation, the sacrificial layers 201 can be made of SiGe and the channel layer 202 can be made of silicon allowing for the selective etching of the sacrificial layers 201. In some embodiments, the selective dry etching etches SiGe at a faster etch rate than it etches Si. As a result, the patterned channel layer 202 laterally extend past opposite end surfaces of the patterned sacrificial layers 201.

Subsequently, inner spacers 207 are filled in the recesses R23, respectively. For example, spacer material layers are formed to fill the recesses R23 left by the lateral etching of the sacrificial layers 201 discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes. After the deposition of the spacer material layer, an anisotropic etching process may be performed to trim the deposited spacer material layer, such that portions of the deposited spacer material layer that fill the recesses R23 left by the lateral etching of the sacrificial layers 201 are left. After the trimming process, the remaining portions of the deposited spacer material are denoted as inner spacers 207 in the recesses R23. The inner spacers 207 serve to isolate metal gates from source/drain regions formed in subsequent processing.

Reference is made to FIG. 27. Source/drain regions 208 are formed in the recesses R22 and connected to the channel layers 202. The source/drain regions 208 may be formed by performing an epitaxial growth process that provides an epitaxial material on the MEOL layer 121. During the epitaxial growth process, the dummy gate layer 204, the gate spacers 206, and the inner spacers 207 limit the source/drain regions 208 to the MEOL layer 121 and the channel layer 202. In some embodiments, the lattice constants of the source/drain regions 208 are different from the lattice constant of the channel layers 202, so that the channel layers 202 can be strained or stressed by the source/drain regions 208 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the channel layer 202.

In some embodiments, the source/drain regions 208 may include Ge, Si, GaAs, AlGaAs, SiGe, GaAsP, SiP, or other suitable material. The source/drain regions 208 may be in-situ doped during the epitaxial process by introducing doping species including: p-type dopants, such as boron or BF₂; n-type dopants, such as phosphorus or arsenic; and/or other suitable dopants including combinations thereof. If the source/drain regions 208 are not in-situ doped, an implantation process (i.e., a junction implant process) is performed to dope the source/drain regions 208. In some embodiments, the source/drain regions 208 can be in an n-type transistor and include SiP.

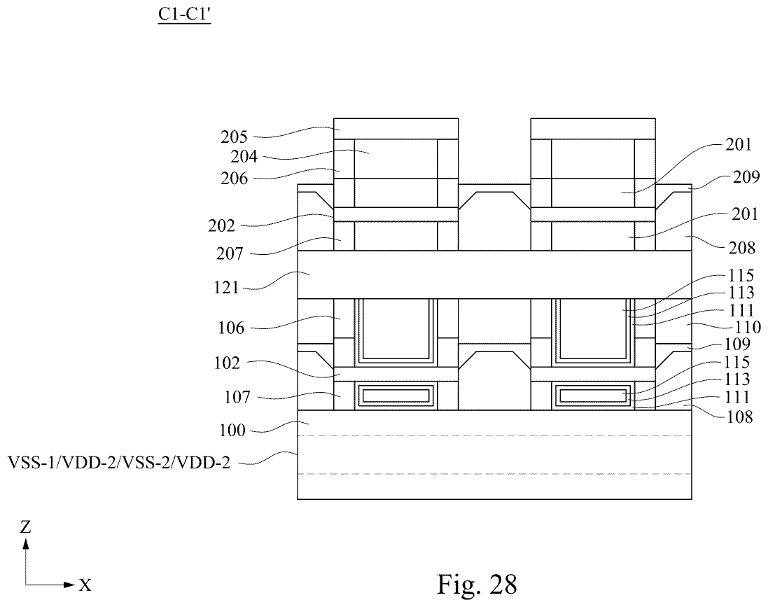

Reference is made to FIG. 28. Source/drain contacts 209 can be formed over the source/drain regions 208. In some embodiments, the source/drain contacts 209 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, other suitable materials, or combinations thereof. In some embodiments, the formation of the source/drain contacts 209 can be performed by such as a lift-off process. By way of example and not limitation, a mask layer (not shown) can be formed by depositing a photoresist layer over the MEOL layer 121 by suitable process, such as spin-coating technique, which may include baking the photoresist layer after coating. In some embodiments, the mask layer may include a photoresist material including positive-type or negative-type resist materials. The mask layer can be patterned to form openings exposing the source/drain contacts 209. Subsequently, a contact material can be deposited over the MEOL layer 121 and formed on the source/drain contacts 209 and on the patterned mask layer. Subsequently, the substrate 100 can be immersed into a tank of appropriate solvent that will react with the patterned mask layer. The patterned mask layer may swell, dissolve, and lift off the contact material formed on the patterned mask layer, portions of the contact material on the source/drain regions 208 are remained to form the source/drain contacts 209.

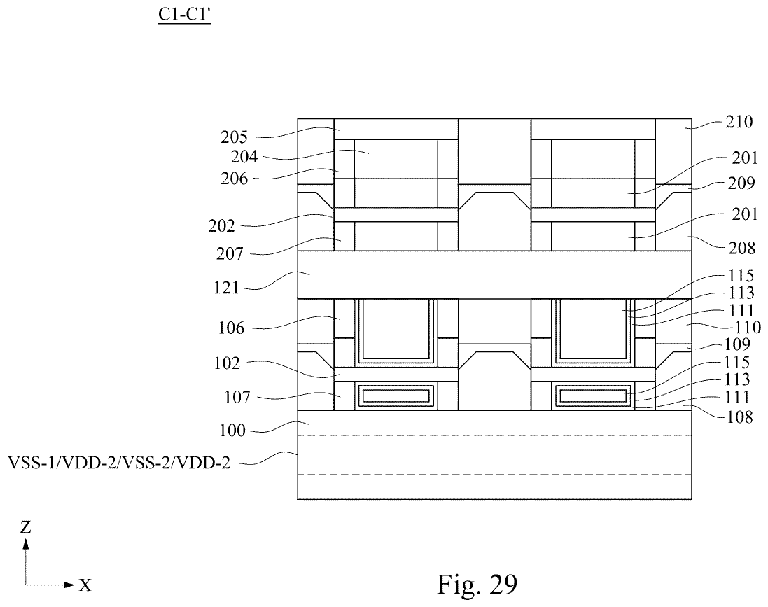

Reference is made to FIG. 29. An ILD layer 210 is formed over the MEOL layer 121. In some embodiments, the ILD layer 210 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the ILD layer 210 may be deposited by a plasma-enhanced chemical vapor deposition (PECVD) process or other suitable deposition technique. In some embodiments, after formation of the ILD layer 210, the substrate 100 may be subject to a high thermal budget process to anneal the ILD layer 210. Subsequently, a planarization process (e.g., CMP) is performed to remove the excessive ILD layer 210 above the hard mask layer 205 until the hard mask layer 205 is exposed. In some embodiments, the hard mask layer 205 may also act as an etch stop layer for etching the ILD layer 210.

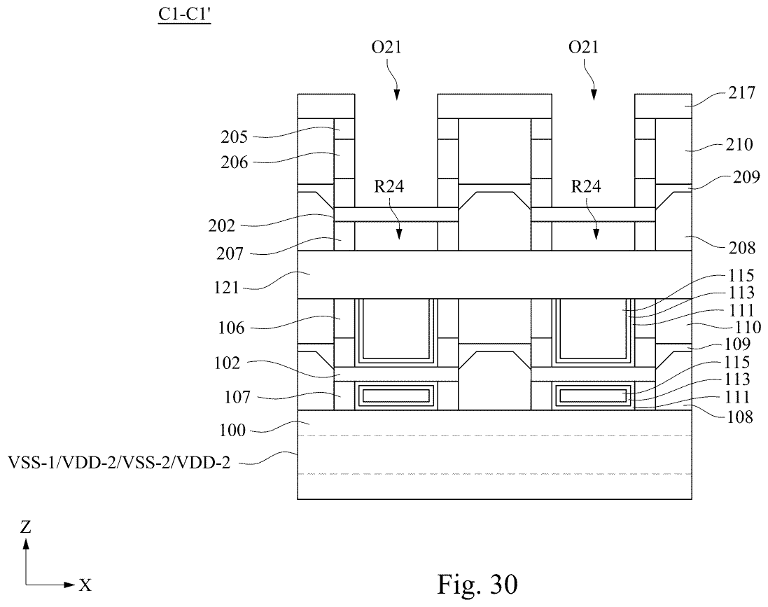

Reference is made to FIG. 30. A hard mask layer 217 may be formed over the ILD layer 210 and the hard mask layer 205. In some embodiments, the hard mask layer 217 may be made of the same material as the ILD layer 210, thereby resulting in a substantially indistinguishable interface between the hard mask layer 217 and the ILD layer 210. In some embodiments, the hard mask layer 217 may be made of a different material than the ILD layer 210. In some embodiments, the hard mask layer 217 may be made of silicon oxide, silicon nitride, silicon oxynitride, silicon carbide, silicon oxycarbide (SiOC), tetraethoxysilane (TEOS), phosphosilicate glass (PSG), borophosphosilicate glass (BPSG), low-k dielectric material, other suitable material, or combinations thereof. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the formation of the hard mask layer 217 can be performed by using any suitable method, such as CVD, physical vapor deposition (PVD), ALD, PEALD, PECVD, SACVD, FCVD, spin-on, and/or the like, or a combination thereof. Subsequently, the hard mask layer 217 may be patterned and then be used to etch the dummy gate layer 204 (see FIG. 29), the hard mask layer 205, and the ILD layer 210. The hard mask layer 217 may be patterned by a lithography process including include photoresist (or resist) coating (e.g., spin-on coating), soft baking, mask aligning, exposure, post-exposure baking, developing the photoresist, rinsing, drying (e.g., hard baking), other suitable processes, and/or combinations thereof. The etching process includes dry etching, wet etching, and/or other etching methods (e.g., reactive ion etching).

After the formation of the patterned hard mask layer 217, the dummy gate layer 204 (see FIG. 29), the hard mask layer 205, and the ILD layer 210 can be etched through the patterned hard mask layer 217 to form an opening O21. The opening O21 can expose a sidewall of the epitaxial stack, such that the channel layer 202 and the sacrificial layers 201 can be exposed from the opening O21. The etching process may include dry etching, wet etching, and/or other etching methods (e.g., reactive ion etching). In some embodiments, the opening O21 may have a rectangular profile extending along Y-direction from the top view. After the formation of the opening O21, the patterned mask can be removed by a suitable technique, such as a wet clean process, an ashing process, or the like.

Subsequently, the sacrificial layers 201 are removed in one or more etching process, so that a recess R24 can be formed to inherit the shape of a lower one of the sacrificial layers 201. The recess R24 can expose a bottom surface of the channel layer 202, and the opening O21 can expose a top surface of the channel layer 202. In some embodiments, the sacrificial layers 201 can be removed by an anisotropic dry etch process. For example, the etching process may include a dry etch process using reaction gas(es) that selectively etch the sacrificial layers 201 at faster rates than channel layer 202.

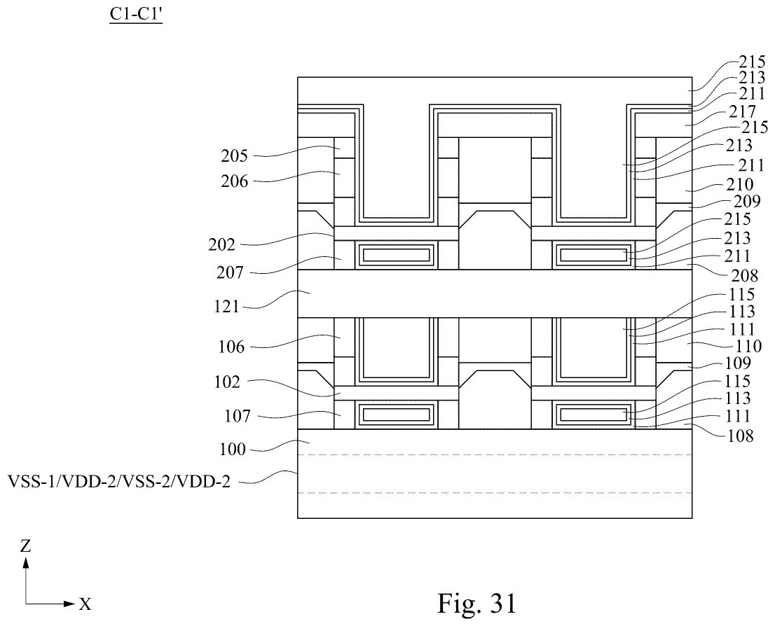

Reference is made to FIG. 31. An interfacial layer 211 and a high-k dielectric layer 213 can be conformally formed over the hard mask layer 217 and in the opening O21 and the recesses R24. In some embodiments, the interfacial layer 211 may include a dielectric material such as silicon oxide (SiO₂), HfSiO, or silicon oxynitride (SiON). In some embodiments, the interfacial layer 211 may be deposited using any suitable method, such as CVD, physical vapor deposition (PVD), ALD, PEALD, PECVD, SACVD, FCVD, spin-on, and/or the like, or a combination thereof. In some embodiments, the high-k dielectric layer 213 may include high-k dielectric material, such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In some embodiments, the high-k dielectric layer 213 may be deposited using any suitable method, such as CVD, physical vapor deposition (PVD), ALD, PEALD, PECVD, SACVD, FCVD, spin-on, and/or the like, or a combination thereof.

Subsequently, a gate electrode layer 215 can be deposited over the high-k dielectric layer 213. The gate electrode layer 215 may include a work function metal layer and/or a fill metal formed around the work function metal layer. The work function metal layer and/or the fill metal may include a metal, metal alloy, or metal silicide. For an n-type FinFET, the work function metal layer may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. On the other hand, for a p-type FinFET, the work function metal layer may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

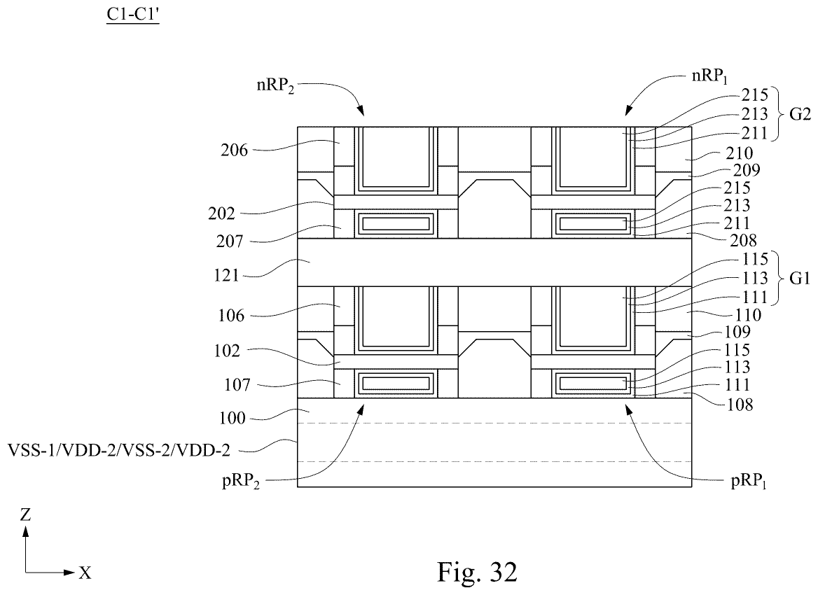

Reference is made to FIG. 32. A planarization process (e.g., CMP) is performed to remove the excessive gate electrode layer 215, the high-k dielectric layer 213, the interfacial layer 211, and the hard mask layers 205 and 217 above the gate spacers 206. The gate spacers 106 may also act as an etch stop layer for etching the gate electrode layer 215, the high-k dielectric layer 213, the interfacial layer 211, and the hard mask layers 205 and 217. Therefore, a (metal) gate structure G2 including the gate electrode layer 215, the high-k dielectric layer 213, and the interfacial layer 211 can be formed in the recesses R24 to surround the channel layer 202 suspended in the recesses R24. In some embodiments, the gate structure G2 may be the final gate of a GAA FET.

Therefore, the semiconductor structure can include the transistors nRP₁, nRP₂, PG_{R}, PG_{L}, PD_{R}, and PD_{L}. The transistor nRP₁ is over the transistor pRP₁, the transistor nRP₂ is over the transistor pRP₂. The transistor PD_{R} is over the transistor PU_{R}. The transistor PD_{L} is over the transistor PU_{L}. The transistors nRP₁, nRP₂, PG_{R}, PG_{L}, PD_{R}, and PD_{L} each includes the channel layer 202, the source/drain regions 208 on opposite sides of the channel layer 202 and connected to the channel layer 202, and the gate structure G2 wrapping around the channel layer 202. In some embodiments, the transistors pRP₁, pRP₂, PU_{R}, and PU_{L} can situated at a first level height, and the transistors nRP₁, nRP₂, PG_{R}, PG_{L}, PD_{R}, and PD_{L} can situated at a second level height higher than the first level heigh. In some embodiments, the transistors nRP₁, nRP₂, PG_{R}, PG_{L}, PD_{R}, and PD_{L} can be interchangeably referred to as top-tier transistors. In some embodiments, the transistors nRP₁, nRP₂, PG_{R}, PG_{L}, PD_{R}, and PD_{L} are of a first conductivity type, and the transistors pRP₁, pRP₂, PU_{R}, and PU_{L} are of a second conductivity type opposite to the first conductivity type. By way of example and not limitation, the transistors nRP₁, nRP₂, PG_{R}, PG_{L}, PD_{R}, and PD_{L} may be n-type transistors, and the pRP₁, pRP₂, PU_{R}, and PU_{L} may be p-type transistors. In some embodiments, the transistors nRP₁, nRP₂, PG_{R}, PG_{L}, PD_{R}, and PD_{L} may be p-type transistors, and the pRP₁, pRP₂, PU_{R}, and PU_{L} may be n-type transistors.

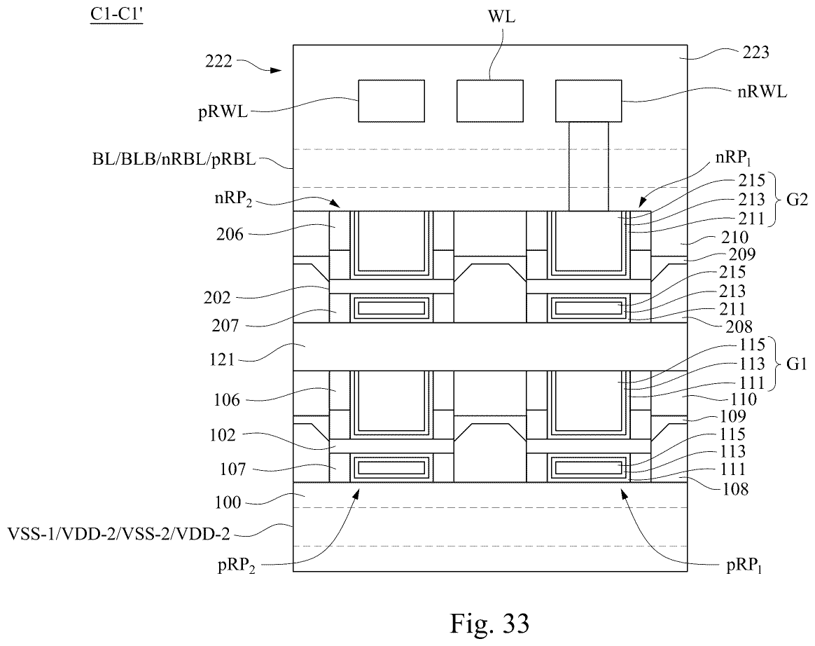

Reference is made to FIG. 33. An interconnect structure 222 can be formed over the transistors nRP₁, nRP₂, PG_{R}, PG_{L}, PD_{R}, and PD_{L}. The interconnect structure 222 may include an inter-metal dielectric 223, the bit lines BL and BLB (see FIG. 2), the read bit lines pRBL and nRBL (see FIG. 2), the word line WL (see FIG. 2), and the read word lines pRWL and nRWL (see FIG. 2) in the inter-metal dielectric 223. In some embodiments, the bit lines BL and BLB and the read bit lines pRBL and nRBL can be formed at a same elevation. In some embodiments, the word line WL and the read word line pRWL and nRWL can be formed at a same elevation higher than the elevation of the bit lines BL and BLB and the read bit lines pRBL and nRBL. In some embodiments, the bit line BL can be electrically connected to the second one of source/drain regions 108 of the underlying transistor PG_{R} through the contact 203m (see FIGS. 2 and 3B). The bit line BLB can be electrically connected to the second one of source/drain regions 108 of the underlying transistor PG_{L} through the contact 203i (see FIGS. 2 and 3B). The read bit line pRBL can be electrically connected to the one of the source/drain regions 108 of the underlying transistor pRP₂ opposite to the transistor pRP₁ through the contact 103f (see FIGS. 2 and 3A). The read bit line nRBL can be electrically connected to the second one of the source/drain regions 108 of the underlying transistor nRP₂ through the contact 203n (see FIGS. 2 and 3B). The word line WL can be electrically connected to the gate structures G2 of the underlying transistors PG_{R} and PG_{R} through the contact 203k (see FIGS. 2 and 3B). The read word line pRWL can be electrically connected to the gate structure G1 of the underlying transistor pRP₂ through the contact 103g (see FIGS. 2 and 3A). The read word linen nRWL can be electrically connected to the gate structure G2 of the transistor nRP₂ through the contact 2030 (see FIG. 3B) and the contact 203p (see FIGS. 2 and 3B).

In some embodiments, the inter-metal dielectric 223 may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bit lines BL and BLB, the read bit lines pRBL and nRBL, the word line WL, and the read word line pRWL and nRWL can be made of tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

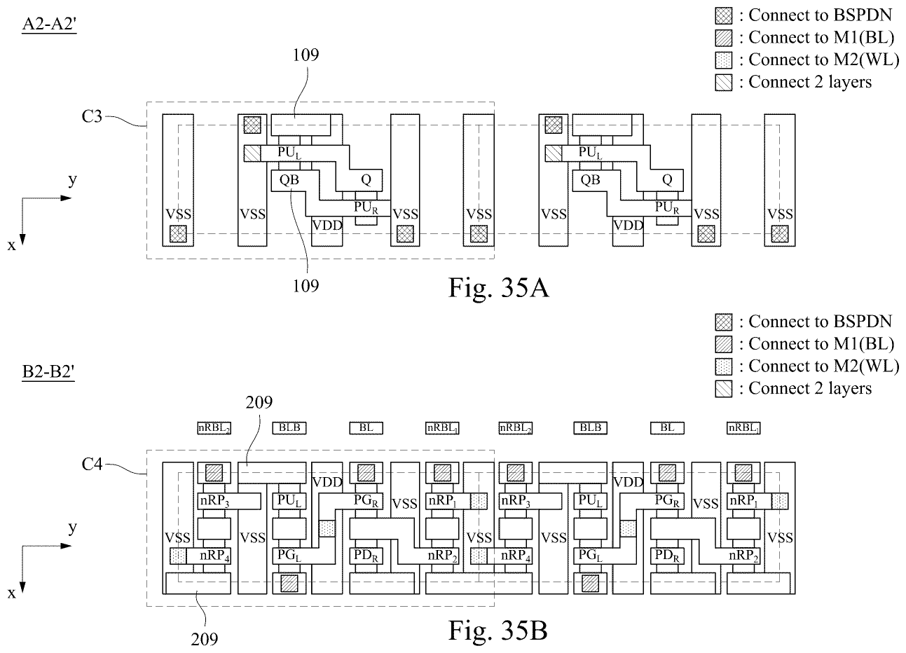

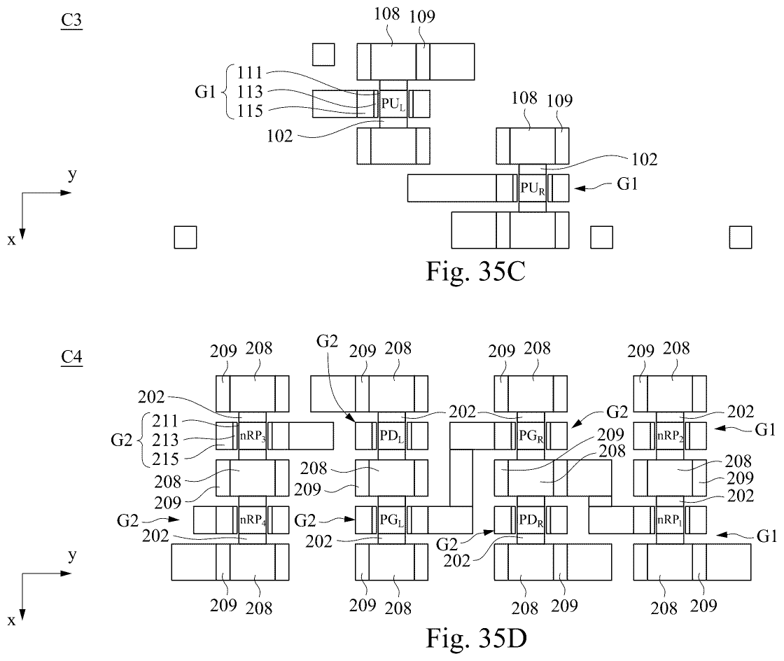

Reference is made to FIGS. 34-35D. FIGS. 34-35D illustrate schematic views of a semiconductor structure of a SRAM bit cell 20 in accordance with some embodiments of the present disclosure. While FIGS. 34-35D illustrate a embodiment of the SRAM bit cell 20 with a different structure configurations than the SRAM bit cell 10 in FIGS. 1-33, the present disclosure may repeat reference numerals and/or letters in the various examples. This repetition is for the purpose of simplicity and clarity and does not in itself dictate a relationship between the various embodiments and/or configurations discussed. Specifically, the SRAM bit cell 20 adopts a different approach by employing NMOS transistors for both read ports, which are positioned at the top-tier of the cell structure, resulting in an 8T footprint.

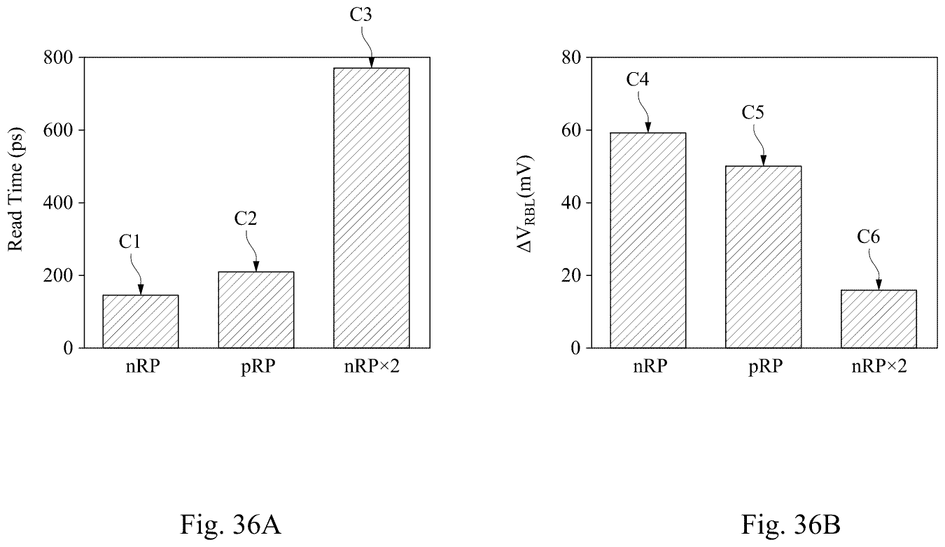

Reference is made to FIG. 36A. FIG. 36A illustrates read times for SRAM bit cells 10 and 20 based on their response to a voltage change (e.g., 30 mv) across their read bit lines. Specifically, data C1 illustrates the read time for read port 12a in SRAM bit cell 10 as it reacts to a voltage change in the bit line pRBL, and data C2 illustrates the read time for read port 14a in the same SRAM bit cell 10, but in response to a voltage change in the bit line nRBL. Additionally, data C3 illustrates the faster read time between the two read ports of SRAM bit cell 20, as both its bit lines nRBL1 and nRBL2 reacts to a voltage change. The SRAM bit cell 10 can be a 10-transistor (10T) structure with dual read ports 12a and 14a. The read port 12a can incorporate PMOS transistors positioned at the bottom-tier, while the read port 14a can incorporate NMOS transistors at the top-tier, enabling the SRAM bit cell 10 to maintain a 6T footprint, as illustrated in FIGS. 2-3E. On the other hand, the SRAM bit cell 20 also be a 10T structure with dual read ports, utilizes NMOS transistors for both read ports at the top-tier, enabling the SRAM bit cell 20 to have an 8T footprint, as illustrated in FIGS. 34-35D. Therefore, the SRAM bit cell 10 can occupy less space (e.g., 6T footprint) compared to the SRAM bit cell 20 (e.g., 8T footprint).

In FIG. 36A, under substantially the same voltage change conditions (e.g., 30 mv), the read times for both read ports 12a and 14a in the SRAM bit cell 10 is shorter than those of the SRAM bit cell 20. In some embodiments, the read time of read port 14a in the SRAM bit cell 10 can be even shorter than its counterpart in the SRAM bit cell 10. The efficiency in the read times of the SRAM bit cell 10 over SRAM cell 20 can be attributed to the more compact size of the SRAM bit cell 10 (e.g., 6T footprint) which in turn has a shorter word line lengths, which reduces word line delay. Therefore, this architectural of the SRAM bit cell 10 not only conserves space within the semiconductor structure but also delivers faster read operations due to minimized word line delays.

Reference is made to FIG. 36B. FIG. 36A illustrates voltage changes for the SRAM bit cells 10 and 20 under a read time condition (e.g., 250 picoseconds (ps)). Specifically, data C4 illustrates the voltage change in the bit line pRBL for the read port 12a in the SRAM bit cell 10 at the specific read time, and data C5 illustrates the voltage change in the bit line nRBL for the read port 14a in the same SRAM bit cell 10. Additionally, data C6 illustrates the minimal voltage change across both bit lines nRBL1 and nRBL1 in the SRAM bit cell 20 under the specific read time. In FIG. 36B, given an equal read time (e.g., 250 ps), the voltage changes in the bit lines pRBL and nRBL for read ports 12a and 12b in the SRAM bit cell 10 can surpass the voltage changes in the bit lines nRBL1 and nRBL2 in the SRAM bit cell 20, indicating that the SRAM bit cell 10 can achieve a higher degree of responsiveness or sensitivity during read operations, which in turn has a quicker read speed compared to the SRAM bit cell 20. In some embodiments, the SRAM bit cell 10 with 10T3P CFET configuration can achieve substantially the same bitcell area as 8-transistor, 2-port (8T2P) CFET SRAM counterpart, yet it may deliver at least about twice the throughput and nearly doubles the area efficiency.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a 10-transistor, 3-port (10T3P) SRAM configuration within the area occupied by a 6-transistor (6T) layout (i.e., 6T footprint). The SRAM bit cell of this disclosure can leverage complementary field-effect transistor (CFET) technology alongside a backside power delivery network (BSPDN). The SRAM bit cell of this disclosure can improve area efficiency, which in turn allows for enhancing high-performance computing, such as compute-in-memory (CIM) applications). Furthermore, the SRAM bit cell of this disclosure can have a read port using pFET-based gates, ensuring optimal performance and space utilization.

In some embodiments, a method includes forming a first read pull-down transistor and a first read pass-gate transistor over a substrate at a first level height, wherein the first read pull-down transistor and the first read pass-gate transistor are of a first read port of a static random access memory (SRAM) cell; forming a second read pull-down transistor and a second read pass-gate transistor over the substrate at a second level height higher than the first level height, wherein the second read pull-down transistor and the second read pass-gate transistor are of a second read port of the SRAM cell. In some embodiments, a footprint of the second read pull-down transistor overlaps with a footprint of the first read pull-down transistor. In some embodiments, the method further includes forming a first write pull-up transistor and a second write pull-up transistor over the substrate at the first level height, wherein the first and second write pull-up transistors are of a write port of the SRAM cell. In some embodiments, the method further includes forming a first write pull-down transistor, a second write pull-down transistor, a first write pass-gate transistor, and a second write pass-gate transistor over the substrate at the second level height, wherein the first and second write pull-down transistors and the first and second write pass-gate transistors are of the write port of the SRAM cell. In some embodiments, a footprint of the first write pull-down transistor overlaps with a footprint of the first write pull-up transistor, and a footprint of the second write pull-down transistor overlaps with a footprint of the second write pull-up transistor. In some embodiments, the first read pull-down transistor and the first read pass-gate transistor are of a first conductivity type, and the second read pull-down transistor and the second read pass-gate transistor are of a second conductivity type opposite to the first conductivity type. In some embodiments, the first read pull-down transistor and the first read pass-gate transistors are of p-type metal-oxide-semiconductor (PMOS) transistors, and the second read pull-down transistor and the second read pass-gate transistor are of NMOS transistors. In some embodiments, the first read pull-down transistor and the first read pass-gate transistor are of n-type metal-oxide-semiconductor (NMOS) transistors, and the second read pull-down transistor and the second read pass-gate transistor are of PMOS transistors. In some embodiments, the method further includes forming a back-side voltage source line over the substrate, wherein the back-side voltage source line is electrically connected to a source/drain region of the first read pull-down transistor. In some embodiments, the method further includes forming a back-side ground line over the substrate, wherein the back-side ground line is electrically connected to a source/drain region of the second read pull-down transistor.

In some embodiments, a method includes forming a first semiconductive nanostructure over a substrate at a first level height; forming a plurality of first epitaxial structures on opposite sides of the first semiconductive nanostructure; forming a first gate structure wrapping around the first semiconductive nanostructure, wherein the first semiconductive nanostructure, the first epitaxial structures, and the first gate structure from a first p-type metal-oxide-semiconductor (PMOS) transistor being a first read port of a static random access memory (SRAM) cell; forming a second semiconductive nanostructure over the substrate at a second level height different than the first level height; forming a plurality of second epitaxial structures on opposite sides of the second semiconductive nanostructure; forming a second gate structure wrapping around the second semiconductive nanostructure, wherein the second semiconductive nanostructures, the second epitaxial structures, and the second gate structure are of a first n-type metal-oxide-semiconductor (NMOS) transistor being a second read port of the SRAM cell. In some embodiments, a footprint of the second semiconductive nanostructure overlaps with a footprint of the first semiconductive nanostructure. In some embodiments, the second level height is higher than the first level height. In some embodiments, the method further includes forming a third semiconductive nanostructure over the substrate at the first level height, and a fourth semiconductive nanostructure over the substrate at the second level height; forming a plurality of third epitaxial structures on opposite sides of the third semiconductive nanostructure, and a plurality of fourth epitaxial structures on opposite sides of the fourth semiconductive nanostructure; forming a third gate structure wrapping around the third semiconductive nanostructure, and a fourth gate structure wrapping around the fourth semiconductive nanostructure, wherein the third semiconductive nanostructure, the third epitaxial structures, and the third gate structure from a second PMOS transistor being a write port of the SRAM cell, and the fourth semiconductive nanostructure, the fourth epitaxial structures, and the fourth gate structure from a second NMOS transistor being the write port of the SRAM cell. In some embodiments, a footprint of the fourth semiconductive nanostructure overlaps with a footprint of the third semiconductive nanostructure.

In some embodiments, a semiconductor structure includes a substrate, a plurality of back-side power lines, and a static random access memory (SRAM) cell. The back-side power lines over a substrate. The SRAM cell is over the back-side power lines. The SRAM cell includes a write port and first and second read ports. The write port includes first and second write pull-up transistors at a first level height. The first read port includes a first read pull-down transistor and a first read pass-gate transistor at a second level height higher than the first level height. The second read port includes a second read pull-down transistor and a second read pass-gate transistor. In some embodiments, the second read pull-down transistor and the second read pass-gate transistor of the second read port of the SRAM cell are at the first level height. In some embodiments, the second read pull-down transistor and the second read pass-gate transistor of the second read port of the SRAM cell are at the second level height. In some embodiments, a footprint of the second read pull-down transistor and the second read pass-gate transistor overlaps with a footprint of the first read pull-down transistor and the first read pass-gate transistor. In some embodiments, the write port of the SRAM cell further comprises first and second write pull-down transistors and first and second write pass-gate transistors at the second level height, wherein a footprint of the first write pull-down transistor overlaps with a footprint of the first write pull-up transistor, and a footprint of the second write pull-down transistor overlaps with a footprint of the second write pull-up transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first read pull-down transistor and a first read pass-gate transistor over a substrate at a first level height, wherein the first read pull-down transistor and the first read pass-gate transistor are of a first read port of a static random access memory (SRAM) cell; and
forming a second read pull-down transistor and a second read pass-gate transistor over the substrate at a second level height higher than the first level height, wherein the second read pull-down transistor and the second read pass-gate transistor are of a second read port of the SRAM cell.

2. The method of claim 1, wherein a footprint of the second read pull-down transistor overlaps with a footprint of the first read pull-down transistor.

3. The method of claim 1, further comprising:
forming a first write pull-up transistor and a second write pull-up transistor over the substrate at the first level height, wherein the first and second write pull-up transistors are of a write port of the SRAM cell.

4. The method of claim 3, further comprising:
forming a first write pull-down transistor, a second write pull-down transistor, a first write pass-gate transistor, and a second write pass-gate transistor over the substrate at the second level height, wherein the first and second write pull-down transistors and the first and second write pass-gate transistors are of the write port of the SRAM cell.

5. The method of claim 4, wherein a footprint of the first write pull-down transistor overlaps with a footprint of the first write pull-up transistor, and a footprint of the second write pull-down transistor overlaps with a footprint of the second write pull-up transistor.

6. The method of claim 1, wherein the first read pull-down transistor and the first read pass-gate transistor are of a first conductivity type, and the second read pull-down transistor and the second read pass-gate transistor are of a second conductivity type opposite to the first conductivity type.

7. The method of claim 6, wherein the first read pull-down transistor and the first read pass-gate transistor are of p-type metal-oxide-semiconductor (PMOS) transistors, and the second read pull-down transistor and the second read pass-gate transistor are of NMOS transistors.

8. The method of claim 6, wherein the first read pull-down transistor and the first read pass-gate transistor are of n-type metal-oxide-semiconductor (NMOS) transistors, and the second read pull-down transistor and the second read pass-gate transistor are of PMOS transistors.

9. The method of claim 1, further comprising:
forming a back-side voltage source line over the substrate, wherein the back-side voltage source line is electrically connected to a source/drain region of the first read pull-down transistor.

10. The method of claim 9, further comprising
forming a back-side ground line over the substrate, wherein the back-side ground line is electrically connected to a source/drain region of the second read pull-down transistor.

11. A method, comprising:
forming a first semiconductive nanostructure over a substrate at a first level height;
forming a plurality of first epitaxial structures on opposite sides of the first semiconductive nanostructure;
forming a first gate structure wrapping around the first semiconductive nanostructure, wherein the first semiconductive nanostructure, the first epitaxial structures, and the first gate structure from a first p-type metal-oxide-semiconductor (PMOS) transistor being a first read port of a static random access memory (SRAM) cell;
forming a second semiconductive nanostructure over the substrate at a second level height different than the first level height;
forming a plurality of second epitaxial structures on opposite sides of the second semiconductive nanostructure; and
forming a second gate structure wrapping around the second semiconductive nanostructure, wherein the second semiconductive nanostructures, the second epitaxial structures, and the second gate structure are of a first n-type metal-oxide-semiconductor (NMOS) transistor being a second read port of the SRAM cell.

12. The method of claim 11, wherein a footprint of the second semiconductive nanostructure overlaps with a footprint of the first semiconductive nanostructure.

13. The method of claim 11, wherein the second level height is higher than the first level height.

14. The method of claim 11, further comprising:
forming a third semiconductive nanostructure over the substrate at the first level height, and a fourth semiconductive nanostructure over the substrate at the second level height;
forming a plurality of third epitaxial structures on opposite sides of the third semiconductive nanostructure, and a plurality of fourth epitaxial structures on opposite sides of the fourth semiconductive nanostructure; and
forming a third gate structure wrapping around the third semiconductive nanostructure, and a fourth gate structure wrapping around the fourth semiconductive nanostructure, wherein the third semiconductive nanostructure, the third epitaxial structures, and the third gate structure from a second PMOS transistor being a write port of the SRAM cell, and the fourth semiconductive nanostructure, the fourth epitaxial structures, and the fourth gate structure from a second NMOS transistor being the write port of the SRAM cell.

15. The method of claim 14, wherein a footprint of the fourth semiconductive nanostructure overlaps with a footprint of the third semiconductive nanostructure.

16. A semiconductor structure, comprising:
a plurality of back-side power lines over a substrate; and
a static random access memory (SRAM) cell over the back-side power lines, the SRAM cell comprising a write port and first and second read ports, wherein the write port comprises first and second write pull-up transistors at a first level height, the first read port comprises a first read pull-down transistor and a first read pass-gate transistor at a second level height higher than the first level height, and the second read port comprises a second read pull-down transistor and a second read pass-gate transistor.

17. The semiconductor structure of claim 16, wherein the second read pull-down transistor and the second read pass-gate transistor of the second read port of the SRAM cell are at the first level height.

18. The semiconductor structure of claim 16, wherein the second read pull-down transistor and the second read pass-gate transistor of the second read port of the SRAM cell are at the second level height.

19. The semiconductor structure of claim 16, wherein a footprint of the second read pull-down transistor and the second read pass-gate transistor overlaps with a footprint of the first read pull-down transistor and the first read pass-gate transistor.

20. The semiconductor structure of claim 16, wherein the write port of the SRAM cell further comprises first and second write pull-down transistors and first and second write pass-gate transistors at the second level height, wherein a footprint of the first write pull-down transistor overlaps with a footprint of the first write pull-up transistor, and a footprint of the second write pull-down transistor overlaps with a footprint of the second write pull-up transistor.
